(19) United States
(12) Patent Application Publication
(10) Pub. No.: US 2023/0226660 A1
(43) Pub. Date: Jul. 20, 2023

(54) POLISHING PAD, POLISHING DEVICE INCLUDING SAME, AND MANUFACTURING METHOD THEREOF

(71) Applicant: KOREA INSTITUTE OF INDUSTRIAL TECHNOLOGY, Cheonan-si, Chungcheongnam-do (KR)

(72) Inventors: Hyoung Jae KIM, Busan (KR); Do Yeon KIM, Busan (KR); Tae Kyung LEE, Yangsan-si Gyeongsangnam-do (KR)

(21) Appl. No.: 17/928,617

(22) PCT Filed: Jul. 10, 2021
(86) PCT No.: PCT/KR2021/008851

§ 371 Date: Nov. 30, 2022

(30) Foreign Application Priority Data
Jul. 16, 2020 (KR) 10-2020-0088114
Jun. 3, 2021 (KR) 10-2021-0071932
Jul. 8, 2021 (KR) 10-2021-0089568

(51) Int. Cl. B24B 37/22; B24B 37/04; B24D 18/00

(52) U.S. Cl. CPC B24B 37/22; B24B 37/04; B24D 18/00

(57) ABSTRACT

Provided are a polishing pad including a porous protrusion pattern, a polishing device including the same, and a manufacturing method of a polishing pad. The polishing pad includes a support layer, and a pattern layer disposed directly on the support layer, the pattern layer comprising a protrusion pattern having a plurality of pores. The pores contribute to an increase in perimeter length of the protrusion pattern in plan view, and a perimeter length of a polishing surface formed by the protrusion pattern per unit area is in a range of 1.0 mm/mm² to 50.0 mm/mm².

### TECHNICAL FIELD

The present disclosure relates to a polishing pad including a protrusion pattern formed on a polishing surface, and a polishing device including the same. More particularly, it relates to a polishing pad capable of reducing manufacturing costs while improving a removal rate by including a porous protrusion pattern, and a polishing device including the same.

Further, the present disclosure relates to a manufacturing method of a polishing pad. More particularly, it relates to a chemical-mechanical polishing pad capable of reducing manufacturing costs while improving a removal rate by including a porous protrusion pattern, and a manufacturing method thereof using a laser.

### BACKGROUND ART

Generally, a chemical mechanical polishing (CMP) process is required to manufacture highly integrated circuit devices such as a semiconductor, a display, and the like. In the chemical mechanical polishing process, a polishing target substrate, e.g., a wafer substrate, is brought into pressure contact with a rotating polishing pad and, at the same time, polishing is performed using chemical reaction with slurry. The chemical mechanical polishing process is intended to planarize a polishing target surface or to remove an unnecessary layer.

The characteristics of the polishing process may be expressed as a removal rate (RR), non-uniformity (NU), scratch of a polishing target, planarization of the polishing target, or the like. Among them, the removal rate is one of the most important characteristics of the polishing process, and a polishing surface morphology (topography) of the polishing pad, a slurry composition, a temperature of a polishing platen, and the like are known as major factors of the removal rate.

A conventional polishing device includes a conditioner to maintain the characteristics of the surface of the polishing pad, i.e., the polishing surface. The conditioner may be located eccentric with respect to the axis of rotation of the polishing pad, and the conditioner may be configured to be in contact with the polishing surface of the polishing pad. Cutting particles made of diamond or the like are disposed on the surface of the conditioner in contact with the polishing pad, and an uneven structure may be formed or maintained on the polishing pad surface due to the cutting particles. That is, during the polishing process, the conditioner continuously may polish the polishing surface of the polishing pad to maintain the surface roughness of the polishing pad above a certain level, and the polishing device including the polishing pad may maintain an approximately constant removal rate.

### DISCLOSURE

### Technical Problem

However, the polishing pad is continuously worn as the polishing process is performed, so that the uneven structure of the surface and the surface roughness may become non-uniform. If the surface roughness is too small, the actual contact area that is actually in contact with the polishing target substrate increases or the flow of polishing liquid slurry is disturbed. On the contrary, if the surface roughness is too large, required planarization may not be satisfied due to non-uniform contact with the polishing target substrate, and scratches may occur on the polishing target. The problem of non-uniformity of the polishing surface is a factor that reduces the lifetime and durability of the polishing pad.

Particularly, the above problem may become serious as a patterned substrate such as a semiconductor or the like becomes highly integrated. For example, in order to form a shallow trench isolation (STI) structure for high integration of a semiconductor, a planarization level of global planarization may be required, and the polishing process may directly affect semiconductor characteristics.

However, the conventional polishing pad is vulnerable to defects such as dishing, erosion, and the like due to a durability problem, and such a problem may cause a serious process failure when the surface of a wafer or the like has a slight curvature. Therefore, there is an urgent demand for development of a polishing pad that may be applied even when a high level of planarization is required as in a shallow trench isolation process.

Accordingly, aspects of the present disclosure provide a polishing pad capable of exhibiting a stable morphology or topography of a polishing surface despite a continued polishing process. Accordingly, there is provided a polishing pad capable of improving usage efficiency of polishing liquid slurry while ensuring excellent removal rate and uniformity.

Further, there is provided a polishing pad capable of controlling a removal rate depending on a polishing target from a newly discovered factor that may affect the removal rate.

Furthermore, there is provided a polishing pad that can be manufactured at lower costs in spite of the improved polishing characteristics as described above.

Aspects of the present disclosure also provide a method of manufacturing a polishing pad including a porous protrusion pattern in a more convenient way.

Aspects of the present disclosure also provide a polishing device including a polishing pad capable of improving usage efficiency of polishing liquid slurry while ensuring excellent removal rate and uniformity.

It should be noted that aspects of the present disclosure are not limited to the above-mentioned aspects, and other unmentioned aspects of the present disclosure will be clearly understood by those skilled in the art from the following descriptions.

### Technical Solution

In one aspect, a polishing pad according to one embodiment of the present disclosure includes a support layer; and a pattern layer disposed directly on the support layer, the pattern layer including a protrusion pattern having a plurality of pores, wherein the pores contribute to an increase in perimeter length of the protrusion pattern in plan view, and a perimeter length of a polishing surface formed by the protrusion pattern per unit area is in a range of 1.0 mm/mm² to 50.0 mm/mm².

A rigidity of the pattern layer may be greater than a rigidity of the support layer.

In plan view, a ratio of an area occupied by the pores to a total area of a top surface of any one protrusion pattern may be 10% to 50%.

Further, a perimeter length of any one protrusion pattern may be 4 times to 50 times a minimum width of the any protrusion pattern.

A perimeter length of the polishing surface formed by the protrusion pattern per unit area may be in a range of 0.1 times to 1.0 times a reciprocal of a minimum width of any protrusion pattern.

A perimeter length of any protrusion pattern may be increased by 1.5 times to 3.5 times compared to a perimeter length when the pores do not exist.

A minimum width of the protrusion pattern may be 20 μm or more, and an average diameter of the pores may be in a range of 10 μm to 150 μm.

In plan view, per unit area, an area occupied by the pores may be 0.5% to 20%.

In plan view, per unit area, an actual polishing area of the protrusion pattern may be 5% to 30%.

Further, the pores may include a third pore which is positioned on a side surface of the protrusion pattern to form a side groove of the protrusion pattern, contributes to an increase in area of the side surface, and affects a flow of slurry during a polishing process.

An average diameter of the third pores may be in a range of 20 μm to 150 μm.

A porosity of the support layer may be different from a porosity of the pattern layer.

In one aspect, a polishing pad according to another embodiment of the present disclosure includes a support layer; and a pattern layer disposed on the support layer, the pattern layer including a protrusion pattern having a plurality of pores, wherein the protrusion pattern has pores exposed on a side surface, and a ratio of a sum of heights occupied by the pores of the side surface to a vertical height of the protrusion pattern is in a range of 10% to 50%.

The average diameter of the pores may be in a range of 20% to 40% of the vertical height of the protrusion pattern.

Further, the pattern layer may include a base and the plurality of protrusion patterns disposed on the base, and a value obtained by subtracting a surface skewness (Rsk_pattern) of a surface of the protrusion pattern from a surface skewness (Rsk_base) of a top surface of the base may be greater than 0.

The pattern layer may include a base and the plurality of protrusion patterns disposed on the base, and an arrangement density of pores on a top surface of the base may be smaller than an arrangement density of pores on a surface of the protrusion pattern.

The pattern layer may include a base and the plurality of protruding patterns disposed on the base, and the base may have an at least partially recessed first trench.

Further, the base may have pores exposed on the inner wall of the first trench, and the average diameter of the pores exposed on the inner wall of the first trench may be in a range of 30 μm to 150 μm.

In addition, the first trench may penetrate the base, and a top surface of the support layer may be at least partially exposed by the first trench.

The support layer may have an at least partially recessed second trench connected to the first trench.

The base may have pores exposed on the inner wall of the first trench, and the support layer have pores exposed on the inner wall of the second trench. An average diameter of the pores on the inner wall of the second trench may be greater than an average diameter of the pores of the inner wall of the first trench.

In addition, the first trench may include a plurality of radial trenches extending radially from a center of a circular polishing pad, and a concentric trench having a concentric shape with respect to the center and connecting the plurality of radial trenches, and a width of the radial trench may be greater than a width of the concentric trench.

The first trench may not penetrate the base, and a surface roughness of a bottom surface of the first trench may be smaller than a surface roughness of an inner wall of the first trench.

A surface skewness of the bottom surface of the first trench may be greater than a surface skewness of the inner wall of the first trench.

In another aspect, a manufacturing method of a polishing pad according to one embodiment of the present disclosure includes preparing a porous pattern layer; and partially removing the pattern layer using a laser, wherein the partially removing of the pattern layer includes forming a base and a plurality of protrusion patterns disposed on the base, and partially removing the pattern layer to have pores exposed on a side surface of the protruding pattern.

The partially removing of the pattern layer may further include forming a trench in the base to have pores exposed on an inner wall of the trench.

Further, the partially removing of the pattern layer may include forming a trench in the base, the trench penetrating the base.

In some embodiments, the manufacturing method may further include disposing the pattern layer on a support layer; and at least partially removing the support layer through the trench penetrating the base.

In another aspect, a manufacturing method of a polishing pad according to another embodiment of the present disclosure includes determining a contact pressure required for polishing and a planar shape and length factor of the protrusion pattern; determining a polishing area of the protrusion pattern in contact with the polishing target substrate in consideration of the contact pressure; determining a perimeter length per unit area of the protrusion pattern in consideration of the determined contact pressure and polishing area; and manufacturing a pattern layer including the protrusion pattern.

The pattern layer may include a protrusion pattern having a plurality of pores, and the pores may contribute to an increase in perimeter length of the protrusion pattern. The pores may contribute to an increase in perimeter length of the protrusion pattern, and also serve to reduce the polishing area, which may improve an actual contact pressure under the same polishing load.

In addition, in the manufacturing of the pattern layer, a length factor of the manufactured protrusion pattern may be greater than the determined length factor.

Before the manufacturing of the pattern layer, the manufacturing method may further include determining a size of pores contained in the protrusion pattern.

In still another aspect, a polishing device according to one embodiment of the present disclosure includes a polishing platen configured to rotate; and a polishing pad disposed on the polishing platen.

Other features and exemplary embodiments may be apparent from the following detailed description, the drawings, and the claims.

### Advantageous Effects

According to embodiments of the present disclosure, it is possible to stably maintain the surface roughness or topography of the polishing surface despite a continued polishing process, and to improve the removal rate and polishing uniformity. Further, even if the surface of the polishing target has a slight curvature, it is possible to follow the curvature of the surface of the target in a vertical direction, thereby improving the removal rate and the polishing uniformity.

Furthermore, the removal rate can be controlled based on factors such as the pattern structure of the polishing pad surface, the length of the pattern, and the contact area of the pattern, and the usage efficiency of the slurry can be improved through the shape and arrangement of unique protrusion patterns according to embodiments of the present disclosure.

Moreover, as above, while the factors such as the structure, length, and/or contact area of the protrusion pattern are configured to satisfy within a predetermined range, the protrusion pattern may have pores of a specified size, so that an edge on which the pores are formed may contribute to an increase in the perimeter length and the like of the protrusion pattern. Accordingly, it is possible to achieve simplification of process equipment for forming the protrusion pattern and contribute to reduction of manufacturing costs of the polishing pad and the polishing device.

Advantageous effects according to the present disclosure are not limited to those mentioned above, and various other advantageous effects are included herein.

### DESCRIPTION OF DRAWINGS

FIG. 1 is a perspective view of a polishing device according to one embodiment of the present disclosure.

FIG. 2 is a plan layout of the polishing pad of FIG. 1.

FIG. 3 is an enlarged perspective view showing portion A of FIG. 2.

FIG. 4 is a plan view illustrating an arrangement of protrusion patterns of FIG. 2.

FIG. 5 is an enlarged perspective view of a protrusion pattern of FIG. 2.

FIG. 6 is a cross-sectional view taken along line B-B′ of FIG. 2.

FIG. 7 is a schematic diagram illustrating a state in which the polishing pad of FIG. 2 is in contact with a polishing target substrate, and FIG. 8 is a schematic diagram compared with FIG. 7.

FIG. 9 is another schematic diagram illustrating a state in which the polishing pad of FIG. 2 is in contact with a polishing target substrate, and FIG. 10 is a schematic diagram compared with FIG. 9.

FIG. 11 is a plan view illustrating an arrangement of protrusion patterns of a polishing pad in a polishing device according to another embodiment of the present disclosure.

FIGS. 12 to 18 are plan views illustrating an arrangement of protrusion patterns of a polishing pad of a polishing device according to still another embodiment of the present disclosure.

FIGS. 19 to 23 are cross-sectional views of a polishing pad of a polishing device according to still other embodiments of the present disclosure, respectively.

FIGS. 24 to 27 are cross-sectional views sequentially illustrating a method of manufacturing a polishing pad according to one embodiment of the present disclosure.

FIG. 28 is an image showing the results according to Experimental Example 1.

FIGS. 29 and 30 are images showing the results according to Experimental Example 2.

FIG. 31 is reference image for explaining skeness.

### MODES OF THE INVENTION

Advantages and features of the present disclosure and methods of accomplishing the same may be understood more readily by reference to the following detailed description of preferred embodiments and the accompanying drawings. The present disclosure may, however, be embodied in many different forms and should not be construed as being limited to the embodiments set forth herein. Rather, these embodiments are provided so that this disclosure will be thorough and complete and will fully convey the concept of the invention to those skilled in the art, and the present disclosure will only be defined by the appended claims. That is, various changes may be made to the embodiments of the present disclosure. However, it is to be understood that the embodiments described below are not intended to limit the embodiments of the present disclosure, and include all modifications, equivalents, and substitutions thereto.

In the drawings, components may be enlarged or reduced in size, thickness, width, length, and the like for convenience and clarity of description, and thus the present disclosure is not limited to the illustrated form.

Unless defined otherwise, all technical and scientific terms used herein have the same meaning as commonly understood by one of ordinary skill in the art to which this invention belongs. Further, unless defined otherwise, all terms defined in generally used dictionaries may not be overly interpreted.

Spatially relative terms, such as “above,” “upper,” “on,” “below,” “beneath,” “lower,” and the like, may be used herein for ease of description to describe one element or feature's relationship to another element(s) or feature(s) as illustrated in the figures. It will be understood that the spatially relative terms are intended to encompass different orientations of the device in use in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below.

As used herein, the term “and/or” includes any and all combinations of one or more of the associated listed items. As used herein, the singular forms “a”, “an” and “the” are intended to include the plural forms as well, unless the context clearly indicates otherwise. It will be further understood that the terms “comprise” and/or “comprising,” when used in this specification, specify the presence of stated components, but do not preclude the presence or addition of one or more other components. A numerical range expressed using ‘to’ indicates a numerical range including values stated before and after ‘to’ as the lower and upper limits. A numerical range expressed using ‘about’ or ‘approximately’ indicates a value or a numerical range within 20% of the value or the numerical range stated after ‘about’ or ‘approximately’.

In this specification, a first direction X indicates an arbitrary direction on the plane, and a second direction Y indicates another direction intersecting the first direction X on the plane. Further, a third direction Z means a direction perpendicular to the plane. Unless otherwise defined, ‘plane’ indicates the plane to which the first direction X and the second direction Y belong. In addition, unless otherwise defined, ‘overlap’ means that components overlap in the third direction Z in the viewpoint of the plane.

As used herein, the term ‘protrusion pattern’ refers to a structure having a shape protruding from a certain reference plane. The arrangement of the pattern may be regular or irregular in plan view. Even if a plurality of protrusion patterns are gathered to form a cluster pattern of a specific shape, and the cluster patterns are substantially regularly arranged, the term ‘protrusion pattern’ may be used to mean any one of a plurality of protrusion patterns forming one cluster pattern.

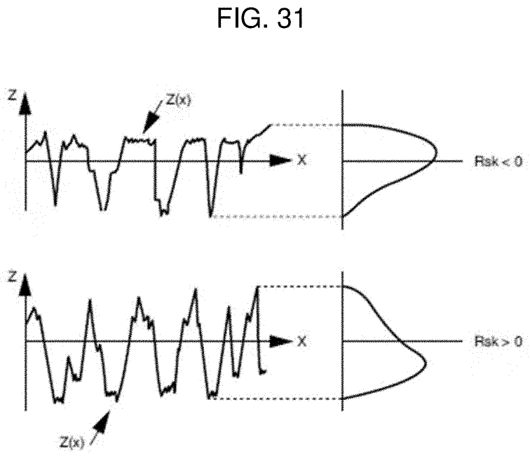

A skewness will be described reference to FIG. 31. In this specification, the surface roughness defined as skewness, or surface skewness may mean a characteristic value indicating the direction and degree of asymmetry with respect to an average value. That is, in the surface roughness, when surface skewness Rsk has a negative value, it means that the tendency of a surface on which a portion recessed from an approximately or relatively flat surface is formed is large. On the other hand, in the surface roughness, when the surface skewness has a positive value, it means that the tendency of a surface on which a portion protruding from an approximately or relatively flat surface is formed is large. In addition, when the surface skewness is zero, it means that the roughness is vertically symmetrical with respect to the average value.

Hereinafter, the present disclosure will be described in detail with reference to the accompanying drawings.

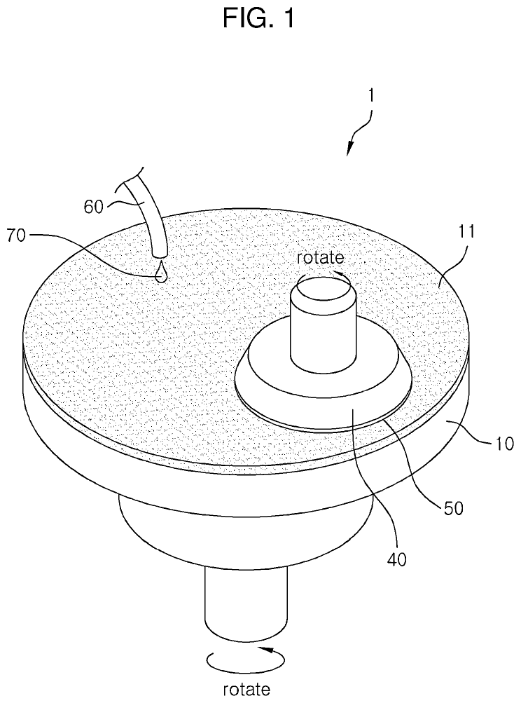

FIG. 1 is a perspective view of a polishing device according to one embodiment of the present disclosure.

Referring to FIG. 1, a polishing device 1 according to the present embodiment may include a polishing platen 10 connected to a rotating shaft and a polishing pad 11 disposed on the polishing platen 10, and may further include a nozzle 60 for supplying a slurry 70 onto a polishing surface of the polishing pad 11, and/or a carrier 40. Although the present disclosure is not limited thereto, the polishing device 1 according to the present embodiment may not require a conditioner for adjusting the surface roughness of the polishing surface of the polishing pad 11.

The polishing platen 10 may be formed in a substantially disc shape and rotate in a counterclockwise direction, for example. Further, the polishing platen 10 may stably support the polishing pad 11 disposed thereon. That is, the polishing platen 10 may function as a rotary table.

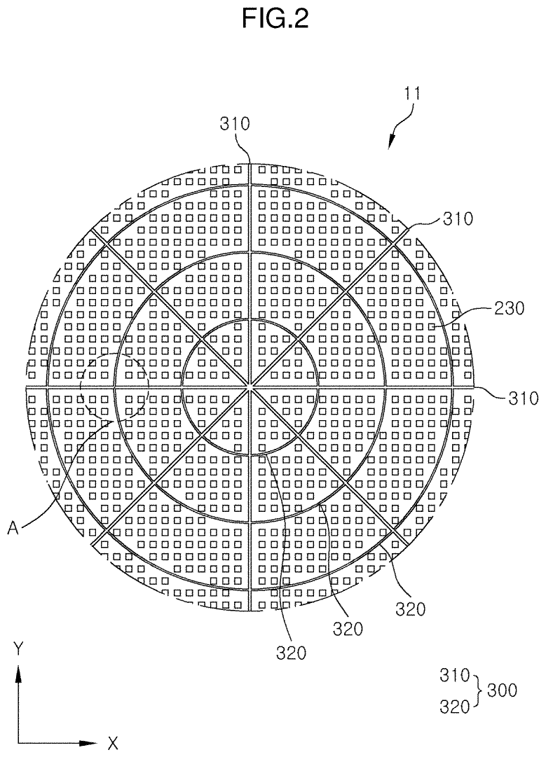

The polishing pad 11 may be disposed on the polishing platen 10. The top surface of the polishing pad 11 in contact with a polishing target substrate 50 may form a polishing surface. Although not shown in FIG. 1, small-sized patterns and/or trenches may have been formed on the polishing surface, i.e., the top surface, of the polishing pad 11. The shape, morphology, or topology of the polishing surface of the polishing pad 11 will be described later in detail with reference to FIG. 2 and the like.

The position of the polishing target substrate 50 may be fixed to be eccentric to the rotation axis of the polishing platen 10 or the rotation axis of the polishing pad 11. The polishing target substrate 50 may be fixed by a carrier 40 connected to the rotation shaft and rotated by the carrier 40. The rotational direction of the polishing target substrate 50 may be the same as the rotational direction of the polishing pad 11, but the present disclosure is not limited thereto, and the rotational directions of the polishing target substrate 50 and the polishing pad 11 may be opposite to each other. The polishing target substrate 50 that is polished by the contact with the polishing pad 11 may be a semiconductor wafer substrate, a display substrate, or the like, but the present disclosure is not limited thereto.

The nozzle 60 may be separated from the polishing pad 11 and may supply the slurry 70 to the polishing surface of the polishing pad 11. In this specification, the term ‘slurry’ may be substantially the same as polishing liquid or polishing particles. The slurry 70 may flow on the polishing surface of the polishing pad 11 by a centrifugal force generated by the rotation of the polishing pad 11, and at least a part of the slurry 70 may penetrate to the space between the polishing pad 11 and the polishing target substrate 50 and contribute to polishing by chemical reaction.

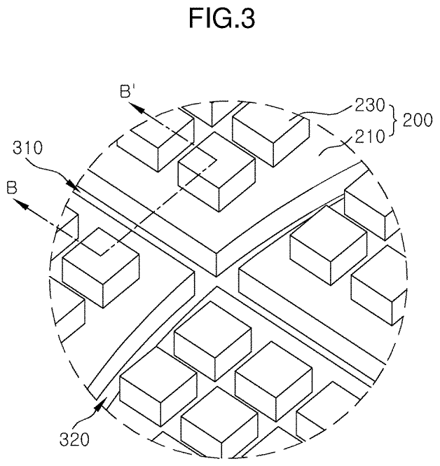

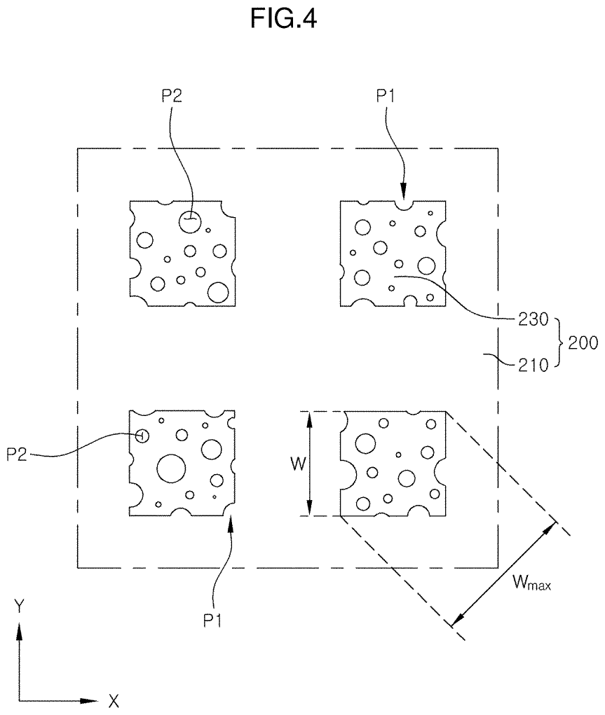

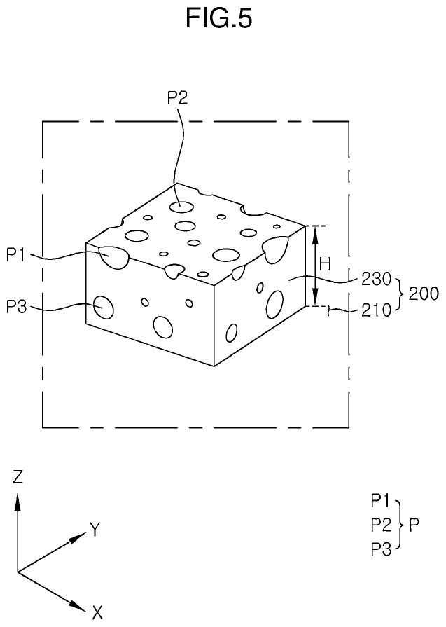

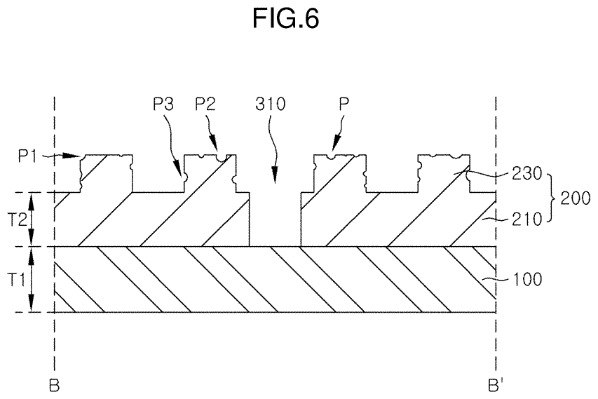

Hereinafter, the polishing pad 11 will be described in detail with further reference to FIGS. 2 to 6. FIG. 2 is a plan layout of the polishing pad of FIG. 1. FIG. 3 is an enlarged perspective view showing portion A of FIG. 2. FIG. 4 is a plan view illustrating an arrangement of protrusion patterns of FIG. 2. FIG. 5 is an enlarged perspective view of a protrusion pattern of FIG. 2. FIG. 6 is a cross-sectional view taken along line B-B′ of FIG. 2.

Referring further to FIGS. 2 to 6, the polishing pad 11 according to the present embodiment may have a substantially circular shape in plan view. Further, the polishing pad 11 may include a support layer 100 and a pattern layer 200 disposed on the support layer 100. The entire top surface of the pattern layer 200 may form a polishing surface. Each of the support layer 100 and the pattern layer 200 may include a material having predetermined flexibility.

In an exemplary embodiment, the strength, rigidity, and/or hardness of the support layer 100 may be smaller than the strength, rigidity, and/or hardness of the pattern layer 200. That is, the support layer 100 may have higher flexibility and a lower modulus of elasticity than those of the pattern layer 200. The modulus of elasticity includes a loss modulus and/or a storage modulus.

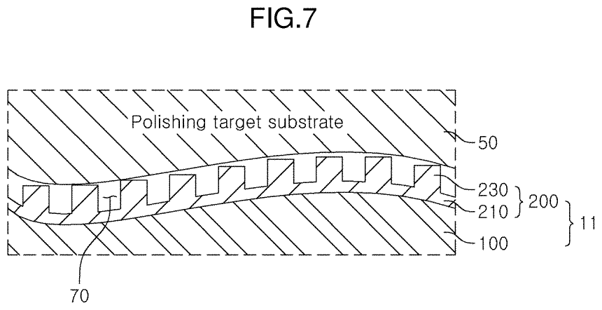

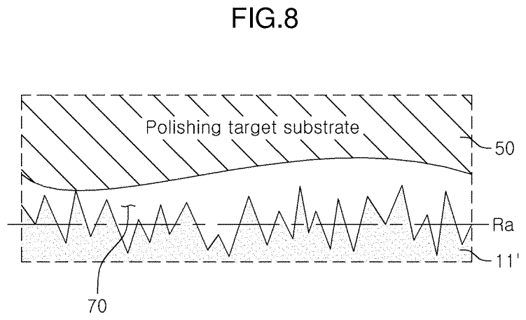

Accordingly, even when the surface of the polishing target substrate 50 has a small curvature, a high planarization characteristic is required for the polishing target substrate 50, and/or the polishing pad 11 has a small curvature, a protrusion pattern 230 formed on the top surface of polishing pad 11 may closely adhere along the curvature of the polishing target substrate 50 to perform polishing. That is, the polishing pad 11 may follow the surface of the polishing target substrate 50. This will be described later in conjunction with FIG. 7 and the like.

The support layer 100 and the pattern layer 200 may be made of the same material or different materials. As a non-limiting example, the support layer 100 and the pattern layer 200 may include substantially the same polymer material. Examples of the polymer material may include (poly)urethane (PU), (poly)(meth)acrylate, (poly)epoxy, acrylonitrile butadiene styrene (ABS), (poly)etherimide, (poly)amide, (poly)propylene, (poly)butadiene, polyalkylene oxide, (poly)ester, (poly)isoprene, (poly)styrene, (poly)ethylene, (poly)carbonate, polyfluorene, polyphenylene, polyazulene, polypyrene, polynaphthalene, poly-p-phenylenevinylene, polypyrrole, polycarbazole, polyindole, polyaniline, or combinations thereof. The rigidity or the like of the support layer 100 and the pattern layer 200 may be controlled by a degree of crosslinking of the polymer material or the like, but the present disclosure is not limited thereto.

The support layer 100 may have a substantially circular shape in plan view, and may function to support the pattern layer 200 disposed thereon. The lower limit of a minimum thickness T1 of the support layer 100 may be about 1 mm or more, about 2 mm or more, or about 3 mm or more. When the thickness of the support layer 100 is smaller than the above range, the support layer 100 may not exhibit sufficient elasticity or strain, and it may be difficult for the polishing pad 11 to follow the curvature of the polishing target substrate 50. The upper limit of the thickness of the support layer 100 is not particularly limited, but may be, for example, about 5 mm or less, or about 4 mm or less. Herein, when a plurality of upper limits and a plurality of lower limits of a numerical range are mentioned, the numerical range disclosed herein should be understood as representing a numerical range between one upper limit arbitrarily selected from the plurality of upper limits and one lower limit arbitrarily selected from the plurality of lower limits.

In some embodiments, the porosity of the support layer 100 may be different from the porosity of the pattern layer 200 to be described later. As a non-limiting example, the support layer 100 may have a porosity greater than that of the pattern layer 200 to be described later, specifically, the protrusion pattern 230. For example, the porosity of the support layer 100 may be greater than or equal to about 1.3 times, about 1.4 times, or about 1.5 times the porosity of the pattern layer 200. As described above, the support layer 100 may have greater flexibility than that of the pattern layer 200. In order to implement this, the type of material, physical properties, and the like may be controlled, but the porosity may also be used. However, the present disclosure is not limited thereto, and in another embodiment, the porosity of the support layer 100 may be smaller than the porosity of the pattern layer 200.

The pattern layer 200 may be disposed on the support layer 100. In an exemplary embodiment, the pattern layer 200 may be directly disposed on the support layer 100 without a separate bonding layer. The pattern layer 200 may include a base 210 and a plurality of protrusion patterns 230 disposed on the base 210. The plurality of protrusion patterns 230 may be spaced apart from each other on the base 210. The surface and/or the inside of the pattern layer 200 may partially have pores. More specifically, the surface of the pattern layer 200 may be in a state in which pores are formed only at specific positions.

The base 210 and the protrusion pattern 230 are integrally and continuously formed without a physical boundary, and may be made of the same material. In another embodiment, the base 210 and the protrusion pattern 230 may be made of different materials with a physical boundary. In this case, the strength, rigidity, and/or hardness of the base 210 may be smaller than that of the protrusion pattern 230.

The base 210 may be a portion overlapping, in the third direction Z, the plurality of protrusion patterns 230 spaced apart from each other. In addition, in plan view, the base 210 may be a portion that covers the support layer 100 while occupying most of an area corresponding to the polishing pad 11. Alternatively, the base 210 may mean the remaining portion of the pattern layer 200 excluding the protrusion pattern 230 to be described later.

The lower limit of a maximum thickness T2 of the base 210 may be about 0.01 mm or more, about 0.05 mm or more, about 0.1 mm or more, about 0.5 mm or more, or about 1.0 mm or more. When the thickness of the base 210 is smaller than the above range, it may be difficult for the polishing pad 11 to follow the curvature of the polishing target substrate 50. The upper limit of the thickness of the base 210 is not particularly limited, but may be, for example, about 3.0 mm or less, about 2.5 mm or less, about 2.0 mm or less, or about 1.5 mm or less.

The plurality of protrusion patterns 230 may be disposed on one base 210. The protrusion pattern 230 may be a portion that forms the uppermost level of the polishing pad 11 and forms the polishing surface. That is, even when the pattern layer 200 has a multi-stage structure, the protrusion pattern 230 may mean a protruding portion contributing to actual polishing.

In an exemplary embodiment, the protrusion pattern 230 may have a substantially quadrangular shape in plan view, but the present disclosure is not limited thereto. In addition, the protrusion pattern 230 may have a substantially quadrangular shape, but may not overlap trenches 300 to be described later in the third direction Z. For example, the protrusion pattern 230 may not be formed at a position overlapping the trench 300, or the already formed protrusion pattern 230 may be removed using a laser or the like.

In addition, although FIG. 2 illustrates a state in which the plurality of protrusion patterns 230 are arranged substantially regularly in plan view, in another embodiment, the plurality of protrusion patterns 230 may be arranged substantially irregularly, or may have a random arrangement. In still another embodiment, the plurality of protrusion patterns 230 may be gathered to form one cluster pattern, and the cluster patterns may be arranged substantially regularly. In this case, the plurality of protrusion patterns 230 in a certain cluster pattern may be arranged with regularity.

In the present embodiment, the protrusion patterns 230 may be repeatedly arranged along at least two directions to form a regular arrangement. For example, the protrusion patterns 230 may be repeatedly arranged at substantially the same distance along the first direction X and the second direction Y in an approximately matrix shape.

The size of the protrusion pattern 230 and the like may be major factors affecting the removal rate, the non-uniformity (NU), and the like of the polishing pad 11. The inventors of the present disclosure have completed the present disclosure by discovering that the removal rate may be controlled by the circumferential length and/or area of the protrusion pattern 230.

In an exemplary embodiment, in plan view, the polishing area occupied by the protrusion patterns 230, or the actual polishing area, i.e., the area occupied by the top surfaces of the protrusion patterns 230 may be about 1.0% or more and 80% or less, or about 1.0% or more and 70% or less, or about 1.0% or more and 60% or less, or about 1.0% or more and 50% or less, or about 1.0% or more and 45.0% or less, or about 1.0% or more and 40% or less, or about 1.0% or more and 35% or less, or about 1.0% or more and 30% or less, or about 3.0% or more and 30.0% or less, or about 5.0% or more and 30.0% or less, or about 10.0% or more and 30.0% or less with respect to the total area. That is, the lower limit of the polishing area with respect to the total area may be about 1.0%, or about 3.0%, or about 5.0%. The upper limit of the polishing area to the total area may be about 80%, or about 70%, or about 60%, or about 50%, about 45%, or about 40%, or about 35%, or about 30%.

As used herein, the term ‘polishing area’ or ‘actual polishing area’ refers to an area where the top ends of the protrusion patterns 230 come into contact with the polishing target substrate 50 to contribute to polishing. That is, it means an area occupied by a portion forming the maximum height in the pattern layer 200 of the polishing pad 11. The polishing area may be calculated as the sum of the top areas of the protrusion patterns 230 with respect to the total area of the polishing pad 11, but the sum of the top areas of the protrusion patterns 230 positioned within a partial unit area with respect to the unit area may also be used as substantially the same meaning.

In addition, as will be described later, the protrusion pattern 230 may have a first pore P1 and a second pore P2 that contribute to an increase in the perimeter length of the edge thereof. In this case, the above-described area occupied by the protrusion pattern 230 may mean an area excluding the area occupied by the first pore P1 and the second pore P2. The first pore P1 and the second pore P2 will be described in detail later.

For example, as shown in FIG. 4, in plan view, when the shape of a certain protrusion pattern 230 is approximately a square with a side length of W, the area occupied by the corresponding protrusion pattern 230 may have a value obtained by subtracting the area occupied by the first pore P1 and the second pore P2 from the square area W×W. Accordingly, an area S occupied by the protrusion pattern 230 may be slightly smaller than the square area W×W. Specifically, the polishing area S formed by any one protrusion pattern 230 may have a value of (W×W)−(area occupied by the first pore+area occupied by the second pore).

For another example, in plan view, when the area occupied by any one protrusion pattern 230 is expressed as S, the ratio occupied by the polishing area may be expressed as S×n with respect to the total area of the polishing pad 11. Here, n is the total number of the protrusion patterns 230 included in the polishing pad 11.

For yet another example, the ratio of the polishing area may be expressed as the area occupied by the protrusion patterns 230 belonging to an arbitrary target area to be checked of the polishing pad 11 with respect to the target area to be checked. In this case, if the x-axis represents the target area to be checked (e.g., inspection area) and the y-axis represents the area occupied by the protrusion patterns 230 in that case, the slope of the graph may express the ratio of the polishing area.

When the ratio (%) of the polishing area is within the above range, an excellent removal rate is exhibited, and the polishing characteristics such as the removal rate and the like may be controlled by changing the arrangement, shape, and/or size of the protrusion patterns 230. In addition, when the polishing area is too large, the removal rate may rather decrease due to the reduction of the actual contact pressure and the restriction of the flow of the slurry.

On the other hand, in plan view, in a unit area, e.g., 1 mm², the perimeter length per unit area formed by the perimeter of the protrusion pattern 230 may be about 1.0 mm/mm² or more and 250.0 mm/mm² or less, or about 1.0 mm/mm² or more and 200.0 mm/mm² or less, or about 1.0 mm/mm² or more and 150.0 mm/mm² or less, or about 1.0 mm/mm² or more and 100.0 mm/mm² or less, or about 1.0 mm/mm² or more and 50.0 mm/mm² or less, or about 1.0 mm/mm² or more and 30.0 mm/mm² or less, or about 1.0 mm/mm² or more and 25.0 mm/mm² or less, or about 1.0 mm/mm² or more and 20.0 mm/mm² or less, or about 1.0 mm/mm² or more and 16.0 mm/mm² or less, or about 1.0 mm/mm² or more and 10.0 mm/mm² or less, or about 3.0 mm/mm² or more and 10.0 mm/mm² or less, or about 5.0 mm/mm² or more and 10.0 mm/mm² or less.

As used herein, the term ‘circumferential length per unit area’ indicates the outer length formed by the polishing area of the protrusion patterns 230 per unit area (1 mm²).

For example, if it is assumed that the entire square shown in FIG. 4 has an area of 1 mm², the perimeter length per unit area may be expressed as four protrusion patterns×L. Here, L denotes a perimeter length of any one protrusion pattern 230. For example, L may be somewhat larger than 4 sides×W. This is because, as described above, the first pore P1 and the second pore P2 cause an increase in the perimeter length of the protrusion pattern 230. That is, in the present disclosure, the perimeter length of the protrusion pattern 230 includes not only the outer edge thereof but also a circumferential length of the second pore P2 positioned inside a closed curve formed by the edge including the first pore P1 of the protrusion pattern 230 having an arbitrary shape in plan view.

For another example, the circumferential length per unit area may be expressed as the circumferential length formed by the protrusion patters 230 belonging to an arbitrary target area to be checked of the polishing pad 11 with respect to the target area to be checked. In this case, if the x-axis represents the target area to be checked (e.g., inspection area) and the y-axis represents the total circumferential length formed by the protrusion patterns 230 in that case, the slope of the graph may express the circumferential length per unit area.

When the above-described perimeter length per unit area (mm/mm²) is in the above range, an excellent removal rate may be exhibited.

In an exemplary embodiment in which the protrusion pattern 230 has a substantially quadrilateral shape in plan view, a maximum width Wₘₐₓ of the protrusion pattern 230 may be formed in a substantially diagonal direction. On the other hand, the minimum width W of the protrusion pattern 230 may correspond to the length of any one side. Herein, the minimum width of the protrusion pattern means the width of a portion having the smallest length among the lengths or widths in plan view of any one protrusion pattern 230 that is physically separated and spaced apart from other protrusion patterns. In addition, the minimum width may mean the minimum length required to be controlled in the process and/or process equipment for forming the protrusion pattern 230, and may mean the shortest distance between one point and another point except for the length increased by the pore.

Although the maximum width Wₘₐₓ of the protrusion pattern 230 may vary depending on the planar shape of the protrusion pattern 230, the maximum width Wₘₐₓ of the protrusion pattern 230 may be about 1.0 mm or less, or about 0.8 mm or less, or about 0.5 mm or less, or about 0.3 mm or less, for example.

The minimum width of the protrusion pattern 230 may correspond to the length W of any one side. The lower limit of the minimum width W of the protrusion pattern 230 may be about 20 μm or more, or about 30 μm, or more, or about 40 μm or more, or about 50 μm or more, or about 60 μm or more, or about 70 μm or more, or about 80 μm or more, or about 90 μm or more, or about 100 μm or more. The upper limit of the minimum width W is not particularly limited, but may be less than the maximum width Wm.

A height H of the protrusion pattern 230 may affect the polishing characteristics and durability of the polishing pad 11. The minimum height H of the protrusion pattern 230 means the shortest vertical distance from the top surface of the base 210 to the top end of the protrusion pattern 230. The minimum height H of the protrusion pattern 230 may be in a range of about 0.01 mm or more and 1.5 mm or less, or about 0.01 mm or more and 1.0 mm or less, or about 0.01 mm or more and 0.5 mm or less, or about 0.01 mm or more and 0.3 mm or less, or about 0.01 mm or more and 0.2 mm or less, or about 0.01 mm or more and 0.1 mm or less.

The height H of the protrusion pattern 230 may have a correlation with the minimum width W of the protrusion pattern 230. That is, if the length ratio of the protrusion pattern 230 on the vertical section becomes too large, for example, if the height H of the protrusion pattern 230 exceeds 1.5 mm, in a process in which the polishing pad 11 comes into close contact with the polishing target substrate 50 while rotating, inclination or distortion may occur in a plane direction, e.g., in an arbitrary direction on a plane to which the first direction X and the second direction Y belong, so that the designed polishing may not be completely performed. On the contrary, when the height H of the protrusion pattern 230 is less than 0.01 mm, the lifetime of the polishing pad 11 may be too short due to damage or abrasion occurring at the upper ends of the protrusion patterns 230 as the polishing process is repeated.

In view of the above, the minimum height H of the protrusion pattern 230 may be in a range of about 0.5 times to 2.5 times, or about 0.6 times to 2.0 times, or about 0.7 times to 1.8 times, or about 0.8 times to 1.7 times, or about 0.9 times to 1.6 times, or about 1.0 times to 1.5 times the minimum width of the protrusion pattern 230.

As described above, the protrusion pattern 230 may have porosity and thus may have a plurality of pores P. The plurality of pores P may include the first pore P1, the second pore P2, and a third pore P3. Herein, the term ‘aperture’ may be used interchangeably with a term such as ‘pore’.

The first pore P1 is exposed on the top surface of the protrusion pattern 230 and is positioned at the edge of the protrusion pattern 230 in plan view to contribute to an increase in the perimeter length L. That is, the first pore P1 may form a recessed portion at the edge of the protrusion pattern 230 in plan view. The first pore P1 may have a shape such as a circular arc or an elliptical arc in plan view.

The second pore P2 may be the same as the first pore P1 in that it is exposed on the top surface, i.e., the polishing surface, of the protrusion pattern 230 and contributes to an increase in the perimeter length L of the polishing surface formed by the protrusion pattern 230. On the other hand, the second pore P2 is different from the first pore P1 in that it does not have a shape forming a recessed portion similarly to the first pore P1, but has a closed curve shape such as an approximate circle, an ellipse, a distorted circle, or a distorted ellipse in plan view.

In an exemplary embodiment, in plan view, with respect to the area of the entire top surface of any one protrusion pattern 230, the ratio of the area occupied by the pores exposed on the top portion of the protrusion pattern 230, i.e., the area occupied by the first pores P1 and the second pores P2 may be in a range of about 10% to 80%, or about 10% to 70%, or about 10% to 60%, or about 10% to 50%, or about 20% to 40%, or about 25% to 35%.

In other words, in any one protrusion pattern 230, the polishing area S formed by the aforementioned one protrusion pattern may be in a range of about 20% to 90%, or about 30% to 90%, or about 40% to 90%, or about 50% to 90%, or about 60% to 80%, or about 65% to 75% of the apparent area, e.g., W×W, of the one protrusion pattern.

The first pores P1 and the second pores P2 may be substantially uniformly distributed. If too many first and second pores P1 and P2 are formed, that is, if the arrangement density or the like is excessively high, too many first pores P1 positioned at the edge may be formed. In this case, the top surface, i.e., the polishing surface, of the protrusion pattern 230 may not have a complete shape, and during the polishing process, for example, the protrusion pattern 230 may collapse, which may cause a reduction in durability. On the other hand, if too few first and second pores P1 and P2 are formed, an increase in the perimeter length of the protrusion pattern 230 may be insignificant.

In the process of manufacturing the polishing pad 11 including the porous protrusion pattern 230 according to the present embodiment, first, the contact pressure required for polishing and the planar shape and length factor of the protrusion pattern 230 may be determined, and the sizes of the pores P included in the protrusion pattern 230 may be determined. In addition, the polishing area, i.e., the top area, of the protrusion pattern 230 may be determined in consideration of the contact pressure. Then, the perimeter length per unit area of the protrusion pattern 230 may be determined in consideration of the determined contact pressure and polishing area, and accordingly, the polishing pad 11 including the pattern layer 200 having the protrusion pattern 230 may be manufactured.

In this case, as described above, it is not easy to simultaneously control the factors, i.e., the perimeter length per unit area and the ratio of the polishing area of the protrusion pattern 230, affecting the removal rate. In particular, there is a limit to increasing the perimeter length per unit area in a state where the required polishing area is determined. When the perimeter length is increased by changing the shape of the pattern, it may cause a reduction in the polishing area, or may cause at least an increase in manufacturing costs due to a reduction in the minimum width of the pattern.

However, according to the present embodiment, it is possible to relatively easily achieve an increase in the perimeter length per unit area while substantially maintaining the polishing area using the pores P of the protrusion pattern 230. When the area ratio of the first pore P1 and the second pore P2 is the same as that described above, the perimeter length of the protrusion pattern 230 having the first pore P1 according to the present embodiment may be increased by about 1.5 times to 3.5 times, or about 2.0 times to 3.0 times, or about 2.2 times to 2.7 times, compared to a case where the first pore P1 and the second pore P2 causing an increase in the perimeter length are not provided.

In addition, a slight difference may occur depending on the planar shape of the protrusion pattern 230, but when the protrusion pattern 230 has an edge extending in the first direction X and the second direction Y as in the present embodiment, the total perimeter length of any one protrusion pattern 230 may be about 4 times to 50 times, or about 5 times to 50 times, or about 8 times to 40 times, or about 10 times to 30 times, or about 15 times to 25 times the minimum width W of the protrusion pattern 230.

Alternatively, the perimeter length formed by the protrusion pattern 230 per unit area may be about 0.1 times to 1.0 times, or about 0.2 times to 0.9 times, or about 0.3 times to 0.8 times the reciprocal of the minimum width W of any one protrusion pattern 230.

Meanwhile, as described above, the lower limit of the ratio of the polishing area occupied by the protrusion patterns 230 with respect to the total area of the polishing pad 11 may be about 1.0%, or about 3.0%, or about 5.0%, or about 10%, and the upper limit thereof may be about 80%, or about 70%, or about 60%, or about 50%, or about 45%, or about 40%, or about 35%, or about 30%.

In this case, the ratio of the area occupied by the first pores P1 and the second pores P2 on the top surface of the protrusion pattern with respect to the total area of the polishing pad 11, or the ratio of the area occupied by the first pores P1 and the second pores P2 per unit area may be about 0.01% to 25%, or about 0.5% to 20%, or about 1.0% to 15%.

Although the present disclosure is not limited to the following, in some embodiments, pores may exist in the remaining portion of the pattern layer 200 except for the protrusion pattern 230, that is, even on the surface of the base 210. However, according to the definition of the first pore P1 and the second pore P2 described above, the ratio of the area occupied by the first pores P1 and the second pores P2 excluding the pores on the surface of the base 210 to the inspection area (unit area) or the total area of the polishing pad 11 may be within the above range.

As the factors affecting the removal rate and the like, in addition to the ratio of the top area (i.e., actual polishing area) of the protrusion pattern 230 and the perimeter length per unit area, the inventors of the present disclosure have discovered another factor in the case where the protrusion pattern 230 has pores P of a predetermined size or more as in the present embodiment, and came to complete the present disclosure. That is, when the area occupied by the pores P as described above, the area occupied by the pores P with respect to the total area, and the area ratio of the top area of the protrusion pattern 230 excluding the area occupied by the pores P are within the above range, excellent polishing properties may be exhibited.

The first pore P1 and the second pore P2 may have substantially the same size. Since the first pore P1 is positioned at the edge of the protrusion pattern 230 and does not have a complete circular or elliptical shape, the size (e.g., diameter or particle size) of the first pore P1 may be understood to correspond to twice the radius of curvature of the arc formed by the first pore P1, but the present disclosure is not limited thereto. If the first pore P1 and the second pore P2 have an elliptical or distorted shape rather than a complete circular shape, the size of the pore means a diameter, i.e., an equivalent diameter, of an imaginary circle corresponding to the area of the pore having a shape such as an ellipse.

The sizes of the pores P, i.e., a distribution range of the diameter and an average diameter may both affect the removal rate, but in particular, the average diameter may be a very important factor. As described above, the arrangement density of the pores P may affect the durability and the edge shape of the protrusion pattern 230, but the average diameter of the pores P may also affect them.

In an exemplary embodiment, the average diameter of the pores P may be in a range of about 10 μm to 150 μm, or about 20 μm to 150 μm, or about 30 μm to 130 μm, or about 50 μm to 110 μm, or about 60 μm to 100 μm.

When the average diameter of the pores P is too large, for example, only about one to three first pores P1, instead of a larger number of first pores P1, may be provided on any one side forming the minimum width of the protrusion pattern 230, or even the size of the first pore P1 may be greater than the length of any one side of the protrusion pattern 230. In this case, it may be difficult to exhibit an effect of substantially increasing the perimeter length, and a reduction in the polishing area of the protrusion pattern 230 may be caused. In addition, a difference between the top area of the protrusion pattern 230 excluding only the area of the first pores P1, and the top area of the protrusion pattern 230 excluding the area of the entire pores P may increase, and the initially designed removal rate may not be realized.

On the other hand, when the average diameter of the pores P is too small, the durability of the protrusion pattern 230 may be deteriorated due to the first pores P1 positioned at the edge of the protrusion pattern 230, and may result in poor polishing.

Despite the difference in the average diameter of the pores P, the arrangement density and distribution of the pores in addition to the area occupied by the pores P may be configured as described above to achieve the intended improvement of the polishing properties.

Although the present disclosure is not limited to the following, the diameter distribution of the pores P including the first pores P1 and the second pores P2 may be in a range of about 1 μm to 500 μm, or about 5 μm to 400 μm, or about 80 μm to 300 μm.

In some embodiments, the side surface of the protrusion pattern 230 may have the third pores P3. That is, the third pore P3 refers to a pore exposed only on the side surface of the protrusion pattern 230, not on the top surface thereof. At least some of the plurality of pores included in the protrusion pattern 230 may be exposed on the side surface of the protrusion pattern 230 to form a recessed groove.

The groove, i.e., the third pore P3, on the side surface of the protrusion pattern 230 is different from the first pore P1 and the second pore P2 in that it is not exposed on the top surface, i.e., the polishing surface, of the protrusion pattern 230, and does not affect an increase in the perimeter length of the top of the protrusion pattern 230.

A predetermined separation distance may be provided between the protrusion patterns 230 adjacent to each other. A polishing liquid, i.e., the slurry 70 flows through the separation space and may affect the polishing properties. If the slurry flow path between the protrusion patterns 230 is too small, a problem such as partial agglomeration of the slurry 70 may occur. There may be a limit to controlling the separation distance between the protrusion patterns 230 having a predetermined shape, and this may cause a reduction in the area of the top portion of the protrusion patterns 230.

The side surface of the protrusion pattern 230 according to the present embodiment may have a predetermined groove formed by the third pore P3, and may contribute to an increase in the flow of the slurry 70 by using the groove. The size and the like of the third pore P3 have been described together with the first pore P1 and the second pore P2, and thus a redundant description thereof will be omitted. For example, the average diameter of the third pore P3 may be in a range of about 20 μm to 150 μm, or about 30 μm to 130 μm, or about 50 μm to 110 μm, or about 60 m to 100 μm.

Although the present disclosure is not limited to the following, when the polishing process is performed using the polishing pad 11 according to the present embodiment, the height H of the protrusion pattern 230 may be gradually lowered while being cut from the top end of the protrusion pattern 230. In this case, as the height of the protrusion pattern 230 is lowered, the third pore P3 may be exposed and may change into the above-described first pore P1.

As described above, the first pore P1 and the second pore P2 contribute to an increase in the perimeter length of any protrusion pattern 230, and may also affect the polishing area formed by the protrusion pattern 230. In addition, the third pore P3 may be exposed on the side surface of the protrusion pattern 230 to affect the flow of the slurry 70.

In the manufacture of the polishing pad 11, for example, when controlling the perimeter length of the protrusion pattern 230 after determining the polishing area in design, the size, such as the width, of the protrusion pattern 230 is very restricted. In addition, when the protrusion pattern 230 is finely formed in order to secure a sufficient perimeter length, it causes an increase in manufacturing costs.

However, when the protrusion pattern 230 forms the plurality of pores as in the present embodiment, the perimeter length greater than or equal to a calculated value may be formed. Therefore, when the protrusion pattern 230 is finely formed even if the manufacturing costs increase as in the prior art, it is possible to achieve a larger increase in the perimeter length. For example, the protrusion pattern 230 of the polishing pad 11 actually manufactured may have a perimeter length greater than the initially determined perimeter length per unit area. On the other hand, even if a larger protrusion pattern 230 is formed than that in the prior art, that is, even if the manufacturing costs are reduced, there is an advantage in that the perimeter length of the conventional level can be secured.

Hereinafter, the trench 300 of the polishing pad 11 will be described. One surface (e.g., the top surface in FIG. 6) of the polishing pad 11 may have the trench 300. The trench 300 may perform a channel function for transporting and discharging the slurry 70 dropped on the top surface of the polishing pad 11. If necessary, the term ‘trench’ used herein may be used interchangeably with terms such as a channel, a groove, a recess, or the like.

The trench 300 may include first trenches 310 having a linear shape extending in the first direction X, the second direction Y, and/or a diagonal direction. The first trench 310 may have a shape extending substantially in a radial direction from the center of the circular polishing pad 11. FIG. 2 illustrates a case in which eight first trenches 310 inclined in the first direction X, the second direction Y, and a 45 degree direction are formed. Accordingly, the polishing pad 11 may be partitioned into eight fan-shaped regions having a central angle of approximately 45 degrees. At least some of the first trenches 310 of the polishing pad 11 according to the present embodiment may extend in the arranging directions, i.e., in the first direction X and the second direction Y, of the protrusion patterns 230. However, the present disclosure is not limited thereto.

The first trenches 310 may induce the slurry 70 to move or flow in a radially outer direction of the polishing pad 11 due to the centrifugal force generated by the rotation of the polishing pad 11. Accordingly, even when the slurry 70 is dropped without moving the nozzle 60, it is possible to coat the slurry 70 on the entire surface of the polishing pad 11 and prevent the slurry 70 from being excessively aggregated on a part of the surface of the polishing pad 11, thereby improving the utilization efficiency of the slurry. In some embodiments, the first trench 310 may be configured to become deeper in an outward direction.

Further, the trench 300 may further include second trenches 320 arranged concentrically with respect to the center of the circular polishing pad 11. Although FIG. 2 illustrates a case in which three second trenches 320 are formed, the present disclosure is not limited thereto. A certain second trench 320 may intersect the plurality of first trenches 310. The second trench 320 may induce the slurry 70 to move or flow in the rotation direction of the polishing pad 11, i.e., the circumferential direction, due to the centrifugal force generated by the rotation of the polishing pad 11.

Although the present disclosure is not limited thereto, the slurry 70 that flows first in the outer direction of the polishing pad 11 by the first trenches 310 may flow in the rotation direction of the polishing pad 11 by the second trenches 320. Therefore, it may be advantageous that the maximum width of the first trench 310 is greater than the maximum width of the second trench 320 in order to prevent aggregation of the slurry 70.

FIG. 6 illustrates a case in which the first trench 310 (and the second trench) has a depth substantially equal to the thickness T2 of the base 210. Accordingly, the top surface of the support layer 100 may be partially exposed through the trench 300. However, the present disclosure is not limited thereto, and in another embodiment, the depth of the trench 300 may be smaller than the thickness of the base 210, and thus the support layer 100 may not be exposed. In another embodiment, the depth of the trench 300 may be greater than the thickness of the base 210, and thus the support layer 100 may also have a shape partially having a trench.

In addition, in the present embodiment, the first trenches 310 and the second trenches 320 may provide predetermined fluidity to each pattern layer 200, and the protrusion patterns 230 of the polishing pad 11 may follow the curvature of the polishing target substrate 50 as described above.

That is, the top surface of the support layer 100 may be partially exposed through the first trench 310 and the second trench 320, and the pattern layer 200 may be separated from each other with respect to the first trench 310. That is, the base 210 partitioned and separated with respect to the first trenches 310 or the like may be disposed on one support layer 100. Accordingly, the fluidity in the plane direction may be obtained by the pressure applied to the pattern layer 200 in the third direction Z, and it is possible to more flexibly follow the curved surface of the polishing target substrate 50 in the vertical direction.

To this end, in some embodiments, the maximum depth of the trench 300, e.g., the maximum depth of the first trench 310 may be greater than the height H of the protrusion pattern 230. In an exemplary embodiment in which the trench 300 is formed in the pattern layer 200, when the maximum depth of the first trench 310 is greater than the height of the protrusion pattern 230, it may be advantageous in terms of fluidity of the pattern layer 200 and following for the polishing target substrate.

Hereinafter, the followability and polishing characteristics of the polishing pad 11 according to the present embodiment will be described with further reference to FIGS. 7 to 10.

FIG. 7 is an exemplary schematic view showing a state in which the polishing pad 11 is in contact with the polishing target substrate 50, and FIG. 8 is an exemplary schematic view showing a state in which the polishing pad polished by a conventional conditioner is in contact with the polishing target substrate 50.

First, referring to FIG. 7, when the bottom surface of the polishing target substrate 50 has a slight curvature, the polishing pad 11 according to the present embodiment may be elastically deformed in the vertical direction, e.g., in a direction of gravity, due to sufficient flexibility of the support layer 100. Accordingly, the top surfaces of the protrusion patterns 230 forming the polishing surface may be in close contact with the curved surface of the polishing target substrate 50, and the slurry may be evenly distributed to the space between the pattern layer 200 and the polishing target substrate 50, thereby achieving an excellent removal rate.

Further, a relatively higher pressure may be applied to the portion where the polishing target substrate 50 convexly protruding relatively downward is in contact with the polishing pad 11 compared to the portion where the polishing target substrate 50 concavely recessed relatively upward is in contact with the polishing pad 11, so that it is possible to minimize the non-uniformity (NU) and achieve uniform polishing.

Particularly, in the polishing pad 11 according to the present embodiment, the rigidity of the pattern layer 200 is greater than that of the support layer 100, so that when the polishing pad 11 is pressed against the polishing target substrate 50, a degree of deformation of the support layer 100 may be greater than those of the protrusion pattern 230 and the base 210 of the pattern layer 200. As a non-limiting example, only the support layer 100 may be flexibly deformed while the pattern layer 200 may not be substantially deformed or may be deformed to a minimum. If the protrusion pattern 230 has excessive flexibility and is easily deformed by vertical pressure, the intended removal rate may not be exhibited due to the shape deformation of the protrusion pattern 230 such as a change in the polishing area and inclination in a horizontal direction.

Accordingly, the support layer 100 is deformed instead of the pattern layer 200 to follow the curvature of the surface of the polishing target substrate 50 and exhibit an excellent removal rate. Although the present disclosure is not limited thereto, as a non-limiting example, the material of the pattern layer 200 including the protrusion patterns 230 may be selected such the maximum rate of change in the plane direction with respect to the pressure in the vertical direction becomes about 20.0% or less, or about 15.0% or less, or about 10.0% or less, or about 5.0% or less.

On the contrary, referring further to FIG. 8, in the case of a conventional polishing pad 11′, it is substantially difficult to exhibit uniform roughness over the entire surface of the polishing pad 11′ even though the surface roughness is maintained by a conditioner (not shown). Accordingly, the polishing pad 11′ cannot be in close contact with the polishing target substrate 50 having a curved surface, which may increase the non-uniformity and even cause a scratch defect.

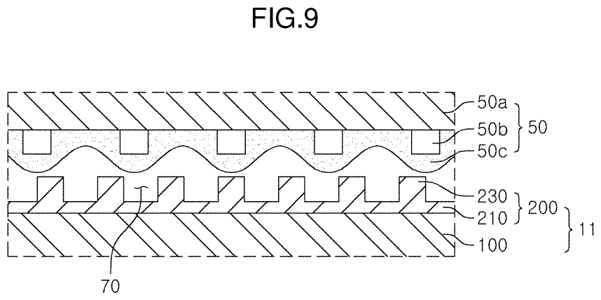

FIG. 9 is another exemplary schematic view showing a state in which the polishing pad 11 is in contact with the polishing target substrate 50, and FIG. 10 is an exemplary schematic view showing a state in which the polishing pad polished by the conventional conditioner is in contact with the polishing target substrate 50. FIGS. 9 and 10 illustrate a case in which the polishing target substrate 50 includes an element pattern 50b disposed on a base substrate 50a and an overcoating layer 50c disposed thereon. The element pattern 50b may be a wiring pattern made of a metal, an active pattern including a semiconductor material, or the like, but is not particularly limited.

First, referring to FIG. 9, when the overcoating layer 50c having very slight curvatures or steps is located on the bottom surface of the polishing target substrate 50, the polishing pad 11 according to the present embodiment may uniformly planarize the overcoating layer 50c with the upper ends of the pattern layer 200 having a uniform height. That is, by selectively polishing only the overcoating layer 50c convexly protruding relatively downward, and minimizing physical pressing on the overcoating layer 50c concavely recessed relatively upward, it is possible to achieve global planarization without damage to the elements of the polishing target substrate 50. Therefore, the polishing pad 11 according to the present embodiment may be applicable to an STI structure process or the like. This will be described later together with experimental examples.

On the contrary, referring further to FIG. 10, in the case of the conventional polishing pad 11′, it is substantially difficult to exhibit uniform roughness over the entire surface, and in some cases, even the overcoating layer 50c that is recessed relatively upward may be polished. Accordingly, the elements of the polishing target substrate 50 are damaged or only partial planarization is achieved, which is not suitable for use in a precision planarization process.

Hereinafter, other embodiments of the present disclosure will be described. However, a description of the configuration that is the same as or extremely similar to that of the polishing pad 11 according to the above-described embodiment will be omitted, and this will be clearly understood by those skilled in the art from the accompanying drawings and detailed description. Further, polishing devices to which polishing pads according to other embodiments are applied are easily conceivable.

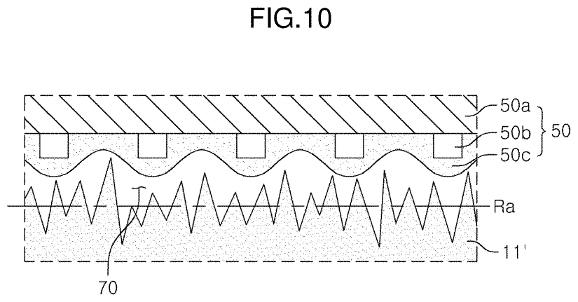

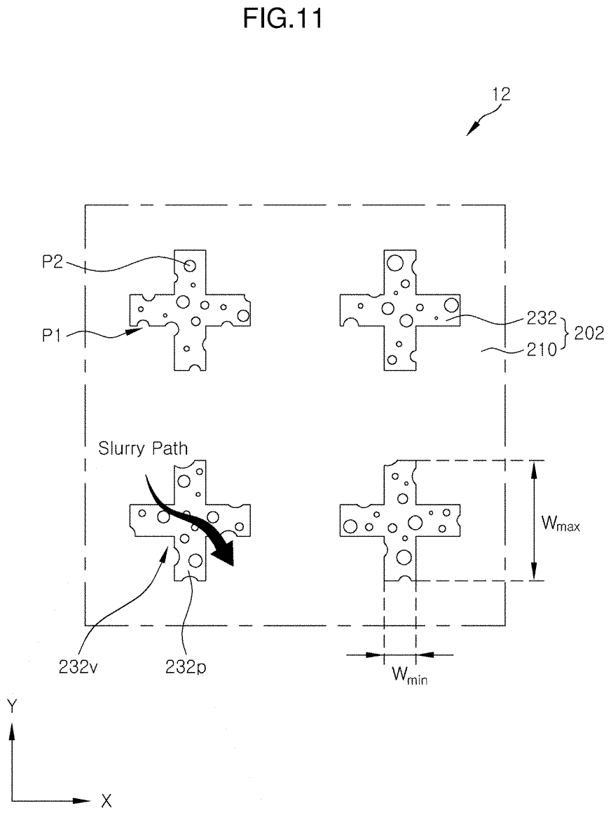

FIG. 11 is a plan view illustrating an arrangement of protrusion patterns of a polishing pad in a polishing device according to another embodiment of the present disclosure.

Referring to FIG. 11, a polishing pad 12 according to the present embodiment is different from the polishing pad according to the embodiment of FIG. 4 and the like in that a protrusion pattern 232 in a pattern layer 202 of the polishing pad 12 has an approximately ‘+’ shape rather than a quadrangular shape in plan view.

A plurality of protrusion patterns 232 may be disposed on the base 210. As described above, the protrusion patterns 232 may be repeatedly arranged along at least two directions to form a substantially regular arrangement. For example, the protrusion patterns 232 may be repeatedly arranged at the same distance along the first direction X and the second direction Y. Although not shown in the drawing, at least some of the first trenches (not shown) extending in the radial direction may be substantially parallel to the arrangement direction of the protrusion patterns 232, but the present disclosure is not limited thereto.

The protrusion pattern 232 may have an approximately ‘+’ shape. Specifically, the protrusion pattern 232 may have extension portions 232p extending in the same first direction X and second direction Y as the arranging directions, with respect to an arbitrary point. Accordingly, the protrusion pattern 232 may have four recessed portions 232v at an upper left portion, an upper right portion, a lower right portion, and a lower left portion in plan view.

In this case, a maximum width Wₘₐₓ of the protrusion pattern 232 may be expressed as the length of two extension portions 232p extending in substantially opposite directions. On the other hand, a minimum width Wₘᵢₙ of the protrusion pattern 232 may be expressed as the width of a certain extension portion 232p.

As described above, the protrusion pattern 232 has the first pore P1 and the second pore P2 contributing to an increase in the perimeter length thereof. In addition, although not shown in the drawing, the protrusion pattern 232 may have the third pore (not shown) positioned on the side surface thereof.

The size and the like of the protrusion pattern 232 may affect the removal rate, the polishing non-uniformity, and the like of the polishing pad 12. In the case of the protrusion pattern 232 having a substantially regular cross shape as in the present embodiment, the perimeter length per unit area of the protrusion pattern 232 may be substantially the same as that in the embodiment of FIG. 4 described above. On the other hand, a polishing area different from that of FIG. 4 may be provided, and design freedom may be secured using the shape of the protrusion pattern 232 as in the present embodiment.

In addition, as in the present embodiment, when a certain protrusion pattern 232 has the recessed portion 232v, the slurry (not shown) flowing on the top surface of the polishing pad 12 may flow in the opposite direction along the top surface of the protrusion pattern 232. That is, the flow of the slurry may be trapped and/or controlled by the recessed portion of the protrusion pattern 232 as well as the top surface of the base 210, so that the slurry may forcibly flow to the top surface of the protrusion pattern 232, and accordingly, the utilization efficiency of the slurry may increase.

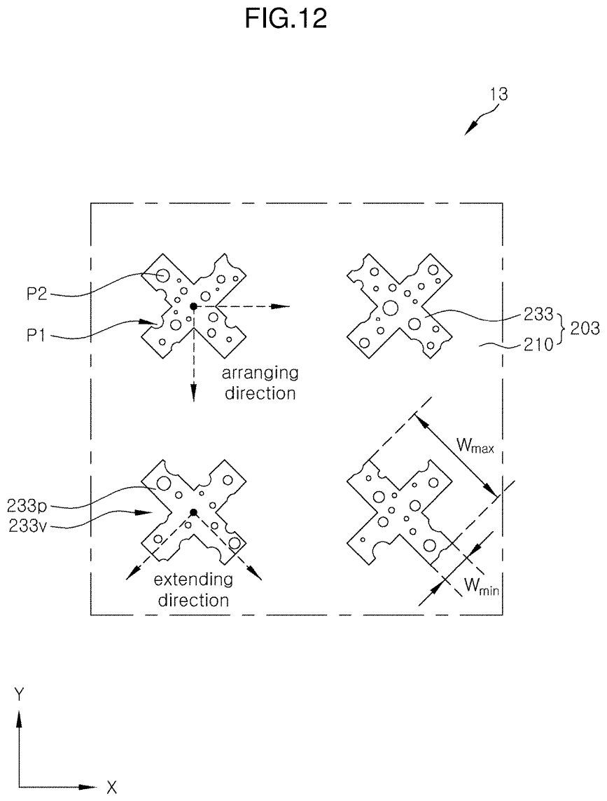

FIG. 12 is a plan view illustrating an arrangement of protrusion patterns of a polishing pad in a polishing device according to still another embodiment of the present disclosure.

Referring to FIG. 12, a polishing pad 13 of the present embodiment is different from the polishing pad according to the embodiment of FIG. 11 in that a protrusion pattern 233 of a pattern layer 203 of the polishing pad 13 has an approximately pivoted ‘+’ shape in plan view. That is, the protrusion pattern 233 may have an approximately ‘X’ shape in plan view. In this specification, the ‘X’ shape may be considered as the same shape as the ‘+’ shape except that it is pivoted.

As described above, the protrusion pattern 233 has the first pore P1 and the second pore P2 contributing to an increase in the perimeter length thereof. In addition, although not shown in the drawing, the protrusion pattern 233 may have the third pore (not shown) positioned on the side surface thereof.

The protrusion pattern 233 may have extension portions 233p extending from an arbitrary point, and the extending direction of the extension portion 233p may be a direction intersecting the arranging direction of the protrusion patterns 233, i.e., the first direction X and the second direction Y. In addition, as described above, a maximum width Wₘₐₓ of the protrusion pattern 233 is expressed as the sum of the lengths of two extension portions 233p, and a minimum width Wₘᵢₙ thereof is expressed as the width of a certain extension portion 233p. The perimeter length per unit area and the planar area of the protrusion pattern 233 according to the present embodiment may be substantially the same as those of the embodiment of FIG. 11.

When the protrusion pattern 233 is pivoted in plan view as in the present embodiment, a recessed portion 233v may be positioned on one side and the other side of the protrusion pattern 233 in the first direction X and in the second direction Y. Although the present disclosure is not limited to the following, the slurry may have a large tendency to move in the radial direction due to centrifugal force generated by rotation of the polishing pad 13. In addition, the radial direction at a certain position may approximately coincide with the first direction X. Therefore, when the recessed portions 233v are arranged as in the present embodiment, the flow structure of the slurry may be strengthened, and the polishing efficiency and the like may be improved.

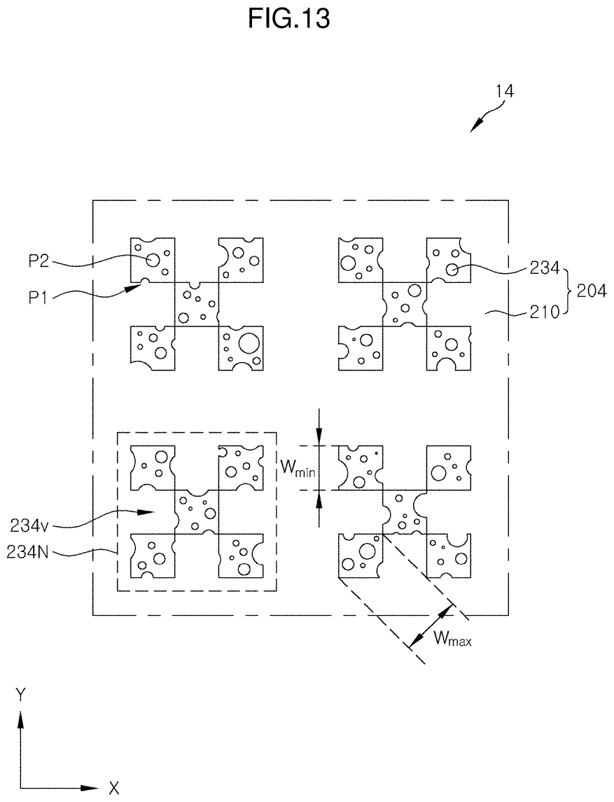

FIG. 13 is a plan view illustrating an arrangement of protrusion patterns of a polishing pad in a polishing device according to still another embodiment of the present disclosure.

Referring to FIG. 13, a polishing pad 14 according to the present embodiment is different from the polishing pad according to the embodiment of FIG. 12 in that a plurality of protrusion patterns 234 in a pattern layer 204 of the polishing pad 14 form a protrusion pattern cluster 234N.

Any one protrusion pattern 234 may have the same shape as that in the embodiment of FIG. 4 and the like. On the other hand, the plurality of protrusion patterns 234 may be adjacent to each other to form the protrusion pattern cluster 234N. A plurality of protrusion pattern clusters 234N may be regularly arranged along the first direction X and the second direction Y.

Any one protrusion pattern cluster 234N may include the plurality of protrusion patterns 234, and the plurality of protrusion patterns 234 may be approximately regularly arranged in any one protrusion pattern cluster 234N. FIG. 13 illustrates a case in which one protrusion pattern cluster 234N includes five protrusion patterns 234.

As described above, any protrusion pattern 234 means a unit structure having a shape independent of other protrusion patterns, and even when the protrusion pattern clusters 234N are regularly arranged, the terms minimum width, maximum width, and the like used herein should be understood as referring to that of any one protrusion pattern 234.

The protrusion pattern cluster 234N may have an approximately ‘X’ shape as a whole. Any one protrusion pattern cluster 234N may have a recessed portion 234v formed by adjacent protrusion patterns 234. The protrusion patterns 234 may be in contact with each other in the diagonal direction, but the present disclosure is not limited thereto.

Each of the protrusion patterns 234 may have the first pore P1 and the second pore P2 that contribute to an increase in the perimeter length thereof. In addition, although not shown in the drawing, each of the protrusion patterns 234 may have the third pore (not shown) positioned on the side surface thereof.

In this embodiment, a maximum width Wₘₐₓ of the protrusion pattern 234 may be expressed as the length in the diagonal direction of the protrusion pattern 234 having a substantially quadrangular shape, and a minimum width Wₘᵢₙ of the protrusion pattern 234 may be expressed as the length of any one side of the protrusion pattern 234.

In this embodiment, in providing the protrusion pattern cluster 234N having the same shape as that of FIG. 12 as a whole, one protrusion pattern cluster 234N may be composed of the plurality of protrusion patterns 234 in order to increase the perimeter length and the like. In this case, a polishing area substantially the same as or similar to that of the embodiment of FIG. 12 may be provided, but the perimeter length per unit area may be further increased. Accordingly, design freedom may be secured.

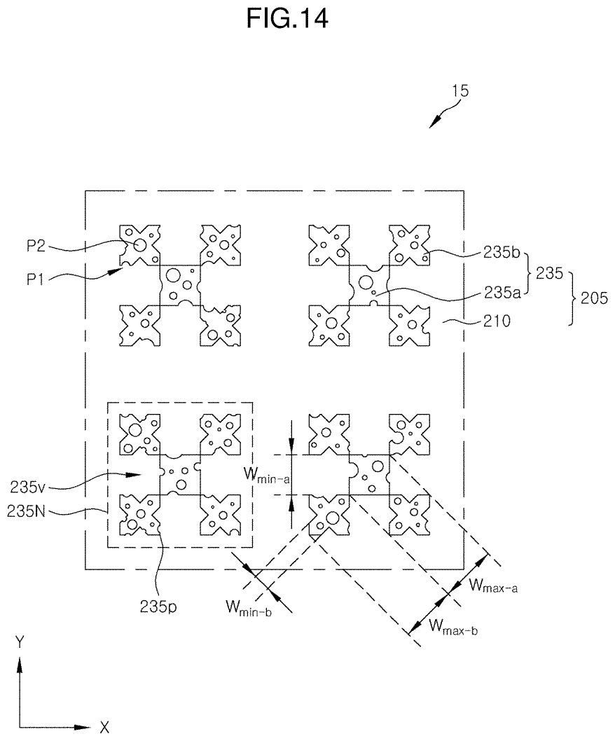

FIG. 14 is a plan view illustrating an arrangement of protrusion patterns of a polishing pad in a polishing device according to still another embodiment of the present disclosure.

Referring to FIG. 14, a polishing pad 15 according to the present embodiment is different from the polishing pad according to the embodiment of FIG. 13 in that a protrusion pattern 235 in a pattern layer 205 of the polishing pad 15 includes a first protrusion pattern 235a and a second protrusion pattern 235b having different shapes.

The first protrusion pattern 235a may be positioned at approximately the center of a protrusion pattern cluster 235N, and may have substantially the same shape as the protrusion pattern according to the embodiment of FIG. 4 and the like. On the other hand, the second protrusion pattern 235b may be arranged to surround the first protrusion pattern 235a and may have an approximately ‘X’ shape.

A plurality of protrusion pattern clusters 235N may be regularly arranged along the first direction X and the second direction Y. FIG. 14 illustrates a case in which any one protrusion pattern cluster 235N includes one first protrusion pattern 235a and four second protrusion patterns 235b. The protrusion pattern cluster 235N may have an approximately ‘X’ shape as a whole. Any one protrusion pattern cluster 235N may have a recessed portion 235v formed by two second protrusion patterns 235b and one first protrusion pattern 235a adjacent to each other. The second protrusion pattern 235b and the first protrusion pattern 235a may be in contact with each other in the diagonal direction, but the present disclosure is not limited thereto.

Any one second protrusion pattern 235b may include four extension portions 235p extending from a certain point. As the second protrusion pattern 235b has an approximately ‘X’ shape, each of the second protrusion patterns 235b may also form a finely recessed portion. The finely recessed portion may allow the flowing slurry to flow in the opposite direction along the top surface of the protrusion pattern 235, thereby further improving the usage efficiency of the slurry.

Each of the first protrusion pattern 235a and the second protrusion pattern 235b may have the first pore P1 and the second pore P2 that contribute to an increase in the perimeter length thereof. In addition, although not shown in the drawing, each of the first protrusion pattern 235a and the second protrusion pattern 235b may have the third pore (not shown) positioned on the side surface thereof.

In this embodiment, a maximum width Wₘₐₓ₋ₐ of the first protrusion pattern 235a may be expressed as the diagonal length of the substantially quadrangular pattern, and a minimum width Wₘᵢₙ₋ₐ of the first protrusion pattern 235a may be expressed as the length of one side thereof. On the other hand, a maximum width W_{max-b} of the second protrusion pattern 235b may be expressed as the sum of the extended lengths of two extension portions 235p extending in opposite directions, and a minimum width W_{min-b} of the second protrusion pattern 235b may be expressed as the width of the extension portion 235p.

According to the present embodiment, while providing a smaller polishing area than that of the polishing pad of FIG. 13, it is possible to provide a larger perimeter length per unit area than that of the polishing pad of FIG. 13. Accordingly, design freedom may be secured.

FIG. 15 is a plan view illustrating an arrangement of protrusion patterns of a polishing pad in a polishing device according to still another embodiment of the present disclosure.

Referring to FIG. 15, a polishing pad 16 according to the present embodiment is different from the polishing pad according to the embodiment of FIG. 14 in that at least some of protrusion patterns 236 in a pattern layer 206 of the polishing pad 16 have an approximately ‘X’ shape, and at least other some have a ‘+’ shape. Accordingly, the protrusion patterns 236 in any one protrusion pattern cluster 236N may be spaced apart from each other. When the plurality of protrusion patterns 236 are spaced apart from each other in a certain protrusion pattern cluster 236N, the separation space may provide a path through which large particles or impurities in the slurry pass. That is, the particles that cause damage to the polishing target substrate do not flow to the top surface of the protrusion pattern 236 but pass through the separation space, thereby further improving the polishing properties.

The protrusion pattern clusters 236N may be regularly arranged in the first direction X and the second direction Y. The protrusion pattern cluster 236N may have an approximately ‘X’ shape as a whole. Any one protrusion pattern cluster 236N may have a recessed portion 236v formed by adjacent protrusion patterns 236.

Any one protrusion pattern 236 may have a plurality of extension portions 236p.

Meanwhile, each of the protrusion patterns 236 may have the first pore P1 and the second pore P2 that contribute to an increase in the perimeter length thereof. In addition, although not shown in the drawing, each of the protrusion patterns 236 may have the third pore (not shown) positioned on the side surface thereof.

In this embodiment, the minimum width Wₘᵢₙ of the protrusion pattern 236 may be expressed as the width of any extension portion 236p.

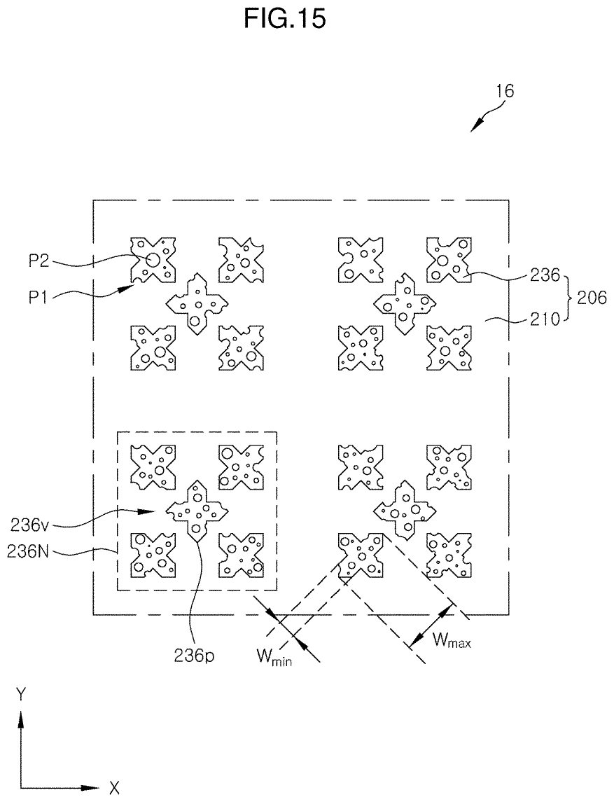

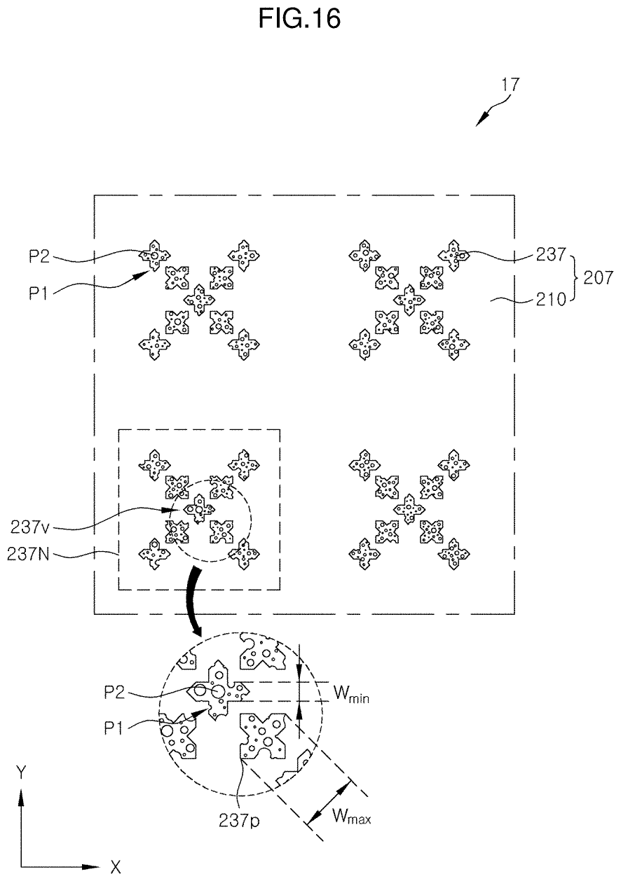

FIG. 16 is a plan view illustrating an arrangement of protrusion patterns of a polishing pad in a polishing device according to still another embodiment of the present disclosure.

Referring to FIG. 16, a polishing pad 17 according to the present embodiment is different from the polishing pad according to the embodiment of FIG. 15 in that a protrusion pattern cluster 237N in a pattern layer 207 of the polishing pad 17 is composed of nine protrusion patterns 237. In this embodiment, the minimum width Wₘᵢₙ of the protrusion pattern 237 may be expressed as the width of one extension portion 237p of any protrusion pattern 237.

The protrusion pattern 237 according to the present embodiment may have a shape substantially similar to that of FIG. 15, and it may be for providing a larger perimeter length.

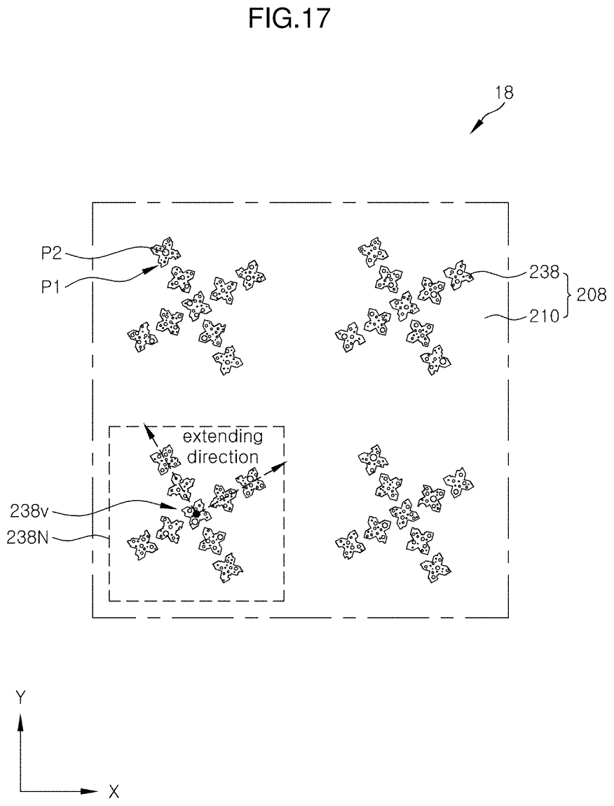

FIG. 17 is a plan view illustrating an arrangement of protrusion patterns of a polishing pad in a polishing device according to still another embodiment of the present disclosure.

Referring to FIG. 17, a polishing pad 18 according to the present embodiment is different from the polishing pad according to the embodiment of FIG. 16 in that the arrangement direction of a plurality of protrusion pattern clusters 238N in a pattern layer 208 of the polishing pad 18 is different from the arrangement direction of protrusion patterns 238 in a certain protrusion pattern cluster 238N.

That is, the plurality of protrusion pattern clusters 238N may be arranged along the first direction X and the second direction Y. The protrusion patterns 238 may be arranged in a direction intersecting the first direction X and the second direction Y. More specifically, the protrusion pattern cluster 238N may have a pivoted shape as a whole.

According to the present embodiment, the arrangement density of the protrusion patterns 238 or the protrusion pattern clusters 238N may be increased, and the polishing area per unit area, the perimeter length per unit area, and the like may be controlled. For example, compared to the case where the arrangement direction of the protrusion pattern clusters and the extension direction of each protrusion pattern cluster, i.e., the arrangement direction of the unit protrusion pattern, are the same as shown in FIG. 16, the arrangement density may be further increased by setting them in different directions as in the present embodiment.

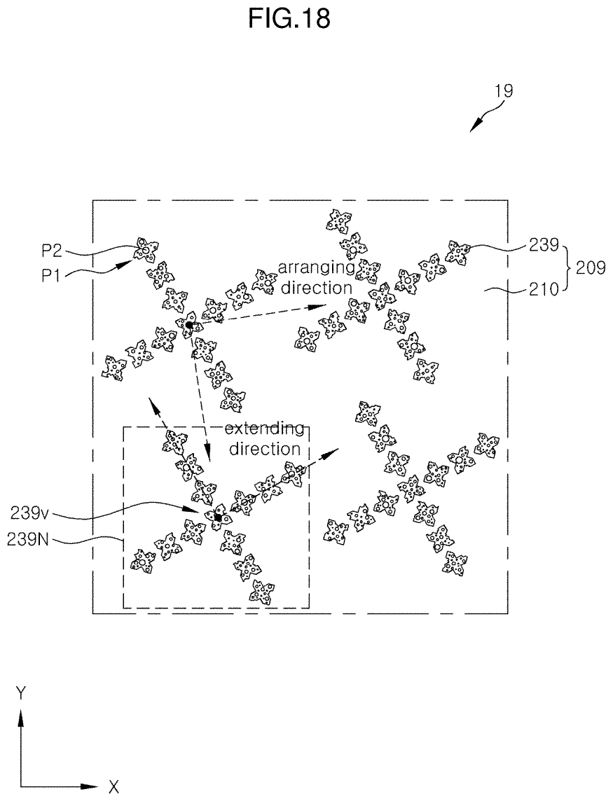

FIG. 18 is a plan view illustrating an arrangement of protrusion patterns of a polishing pad in a polishing device according to still another embodiment of the present disclosure.

Referring to FIG. 18, a polishing pad 19 according to the present embodiment is different from the polishing pad according to the embodiment of FIG. 17 in that the arrangement direction of protrusion pattern clusters 239N in a pattern layer 209 of the polishing pad 19 intersects the first direction X and the second direction Y.

As described above, the first direction X and the second direction Y may be substantially parallel to a direction in which some of the first trenches (not shown) extending in the radial direction extend. That is, in the polishing pad 19 according to the present embodiment, the arrangement direction of the protrusion pattern clusters 239N and the arrangement direction of the protrusion patterns 239 in any one protrusion pattern cluster 239N may be different from the extension direction of the first trench.

FIG. 18 illustrates a case in which the arrangement direction of the protrusion pattern clusters 239N and the arrangement direction of the protrusion patterns 239 are substantially the same, but in another embodiment, both directions may also intersect each other.

Hereinafter, a cross-sectional structure of a polishing pad according to still other embodiments of the present disclosure will be described. Although not shown in the drawing, the polishing pads of embodiments to be described below may have the various planar structures described above.

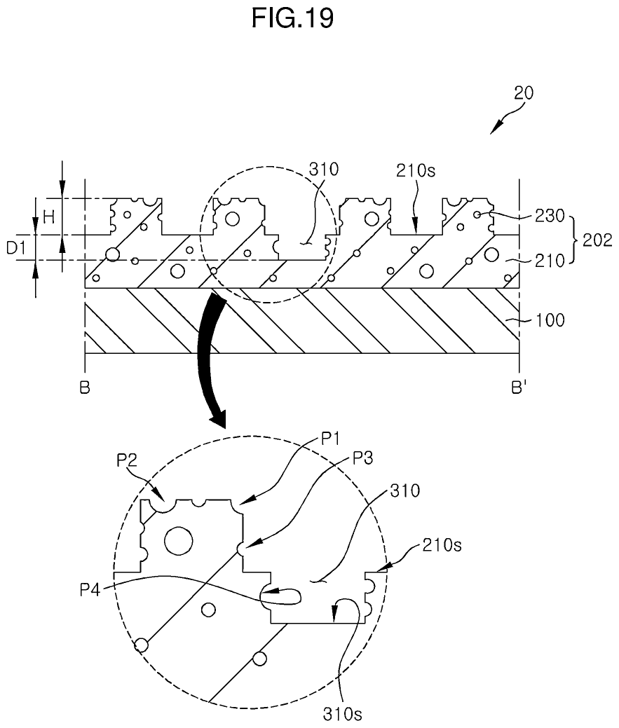

FIG. 19 is a cross-sectional view of a polishing pad in a polishing device according to still another embodiment of the present disclosure, and shows a position corresponding to that of FIG. 6.

Referring to FIG. 19, a pattern layer 202 of a polishing pad 20 according to the present embodiment may have a plurality of pores P1, P2, P3, and P4. The pores P1 to P4 may include the first pore P1 and the second pore P2 positioned on the top surface of the protrusion pattern 230, and may further include the third pore P3 exposed on the side surface of the protrusion pattern 230.

As described above, the size of the pores P is a very important factor in that it affects the polishing efficiency by causing an increase in the perimeter length on the polishing surface and a change in the polishing area by the pores P1 and P2 in plan view. In addition, in particular, in the case of the third pore P3, it may be exposed to the side surface of the protrusion pattern 230, thereby affecting durability and the like of the protrusion pattern 230.

From this point of view, on any cross section, the ratio of the sum of the heights occupied by the third pores P3 to the vertical height H of the protrusion pattern 230 may be in a range of about 10% to 50%, or about 15% to 50%, or about 20% to 50%, or about 20% to 45%, or about 20% to 40%. In addition, the average diameter of the third pore P3 may be in a range of about 5% to 15%, or about 10% to 15% of the height H of the protrusion pattern 230.

When the diameter of one third pore P3 or the sum of the diameters of the third pores P3 is too large, the protrusion pattern 230 may have too much fluidity in the third direction Z, and/or the durability of the protrusion pattern 230 may be degraded. Therefore, it may be preferable to make the diameter of one third pore P3 and the sum of the lengths in the third direction Z occupied by the plurality of third pores P3 arranged in the third direction Z fall within the above range.

In some embodiments, there may be substantially no pores, a relatively small number of pores, or a relatively small size of pores in the remaining portion of the pattern layer 202 except for the protrusion patterns 230, i.e., on the surface such as a top surface 210s of the base 210.

For example, a surface roughness Rsk_base defined as the skewness of the top surface 210s of the base 210 may be greater than a surface roughness defined as the skewness formed by the first pores P1 to the third pores P3 of the surface of the protrusion pattern 230. The surface skewness of the surface of the protrusion pattern 230 may have a negative value, and the surface skewness of the top surface 210s of the base 210 may have a negative value, zero, or a positive value.

Although the present disclosure is not limited thereto, this may be because, when the pattern layer 202 of the polishing pad 20 is formed using a laser or the like, the skewness of the top surface 210s of the base may be adjusted in a more positive direction than the skewness on the protrusion pattern 230 by using the characteristic that at least a part of the pore melts or collapses during the laser irradiation onto the surface of the base 210. The surface roughness may be measured for an inspection area of about 0.1 mm² or more.

Therefore, a value obtained by subtracting a skewness Rsk_pattern of the surface, e.g., the top surface, of the protrusion pattern 230 from the skewness Rsk_base of the top surface 210s of the base may have a positive value greater than zero. That is, a value of the surface state before applying the pad to polishing or the surface state during processing by applying the pad to polishing may be (Rsk_base−Rsk_pattern)>0.

When the upper portion of the protrusion pattern 230 is manufactured to have negative skewness, since the portion of the protrusion pattern 230 excluding pores is flat, it is possible to improve the characteristics of flatly polishing the element pattern 50b formed on the surface of a polishing target wafer and the pattern of the overcoating layer 50c disposed thereon. In addition, by increasing the skewness of the top surface 210s of the base in a more positive direction than the skewness of the protrusion pattern 230, it is possible to improve the controllable characteristics so that the flow of the slurry does not stagnate by too deep pores on the top surface 210s of the base, or so that the residual polishing particles and by-products can be removed from the base 210 without stagnating in the deep pores.

For another example, the arrangement density of the pores (not shown) positioned on the top surface 210s of the base 210 may be smaller than the arrangement density of the pores, i.e., the first pores P1 to the third pores P3, on the surface of the protrusion pattern 230. Specifically, with respect to the total area of the polishing pad 20, the ratio of the area occupied by the pores on the top surface of the base 210 except for the first pores P1 and the second pores P2 may be about 5% to 50%, or about 10% to 30%.

In addition, the pores P1, P2, P3, and P4 may further include a fourth pore P4. The inner wall of the trench 310 formed in the pattern layer 202 may have exposed pores. The pore exposed on the inner wall of the trench 310 may be defined as the fourth pore P4. The average diameter of the fourth pores P4 may be in a range of about 10 μm to 150 μm, or about 20 μm to 150 μm, or about 30 μm to 150 μm, or about 50 μm to 130 μm, or about 60 μm to 100 μm.

On the other hand, there may be substantially no pores, a relatively small number of pores, or a relatively small size of pores on a bottom surface 310s of the trench 310.

For example, the surface skewness Rsk of the bottom surface 310s of the trench 310 may be greater than the surface skewness formed by the fourth pores P4 of the inner wall of the trench 310. The surface skewness of the inner wall surface of the trench 310 may have a negative value, and the bottom surface 310s may have a negative value, zero, or a positive value. More specifically, a value obtained by subtracting the surface skewness of the inner wall from the surface skewness of the bottom surface 310s may have a positive value greater than zero.

For another example, the arrangement density of the pores (not shown) positioned on the bottom surface of the trench 310 may be smaller than the arrangement density of the pores i.e., the fourth pores P4, on the inner wall of the trench 310. Specifically, the ratio of the area occupied by the pores of the bottom surface of the trench 310 may be about 5% to 50%, or about 10% to 30%.

A depth D1 of the trench 310 may be smaller than the thickness, e.g., the maximum thickness, of the base 210. Accordingly, the support layer 100 may not be visually recognized through the trench 310 and may be covered by the remaining pattern layer 202.

In addition, the depth of the trench 310, e.g., the depth D1 of the radial trench 310 may be greater than the maximum height of the protrusion pattern 230. As will be described later, the trench 310 may contribute to the fluidity of the pattern layer 202. Accordingly, it may be desirable for the trench 310 to have a sufficient depth in terms of fluidity of the pattern layer 202 and following for the polishing target substrate.

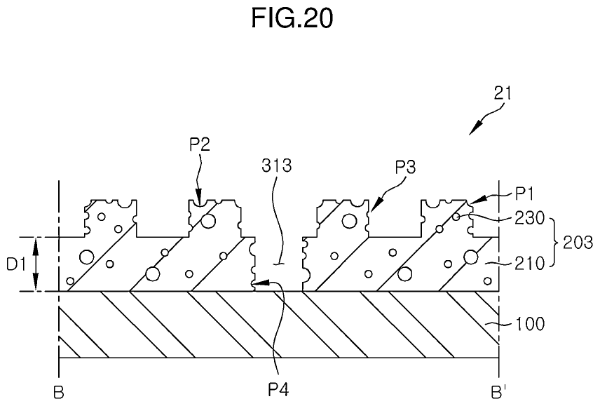

FIG. 20 is a cross-sectional view of a polishing pad in a polishing device according to still another embodiment of the present disclosure, and shows a position corresponding to that of FIG. 6.

Referring to FIG. 20, a polishing pad 21 according to the present embodiment is different from that of the embodiment of FIG. 19 described above in that the top surface of the support layer 100 is partially visible through a trench 313.

A depth D1 of the trench, e.g., the radial trench 313, may be substantially equal to the thickness, e.g., the maximum thickness, of the base 210. Accordingly, the top surface of the support layer 100 may be exposed through the trench 313.

In this embodiment, a trench including the radial trench 313 and/or a concentric trench (not shown) may provide predetermined fluidity to the pattern layer 203, and as described above, the protrusion patterns 230 of the polishing pad 21 may follow the curvature of the polishing target substrate. That is, the top surface of the support layer 100 may be partially exposed through the trench 313, and the base 210 of the pattern layer 203 may be separated with respect to the radial trench. As described above, any one of the pattern layers 203 separated from each other has an approximately sectoral shape in plan view.

By the pressure applied to the pattern layer 203 in the third direction Z by the base 210 partitioned and separated with respect to the radial trench 313 and the like on one support layer 100, it is possible to have fluidity in the plane direction, and to more flexibly follow the curved surface of the polishing target substrate in the vertical direction.

Since the first pore P1 to the third pore P3 of the protrusion pattern 230 and the fourth pore P4 of the base 210 have been described above, a redundant description thereof will be omitted.

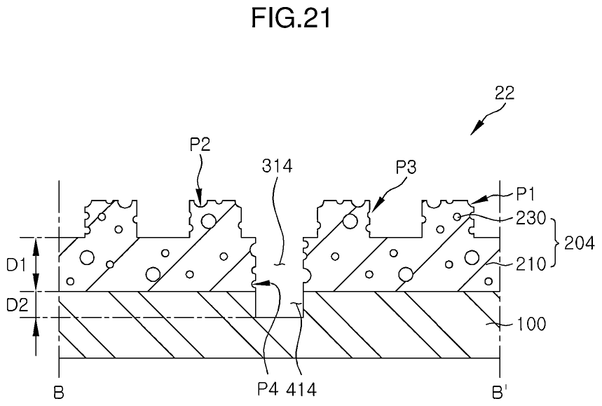

FIG. 21 is a cross-sectional view of a polishing pad in a polishing device according to still another embodiment of the present disclosure, and shows a position corresponding to that of FIG. 6.

Referring to FIG. 21, a polishing pad 22 according to the present embodiment is different from that of the embodiment of FIG. 20 described above in that the support layer 100 also partially has a recessed trench.

In an exemplary embodiment, a pattern layer 204 may have a first trench 314, and the support layer 100 may have a second trench 414. A depth D1 of the first trench 314 may be substantially equal to the thickness of the base 210. A depth D2 of the second trench 414 may be smaller than the thickness of the support layer 100.

The first trench 314 and the second trench 414 may be connected to each other while overlapping each other in the third direction Z. The first trench 314 and the second trench 414 may each include the aforementioned radial trench and/or concentric trench.

The support layer 100 may have the second trench 414 and provide a channel through which the slurry flows. In some embodiments, the second trench 414 of the support layer 100 may or may not have pores on its inner wall. For example, the average diameter of the pores (not shown) on the inner wall of the second trench 414 in the support layer 100 may be greater than the average diameter of the fourth pores P4. For another example, the arrangement density of the pores (not shown) on the inner wall of the second trench 414 may be greater than the arrangement density of the fourth pores P4 on the inner wall of the first trench 314.

Since the first pore P1 to the third pore P3 of the protrusion pattern 230 and the fourth pore P4 of the base 210 have been described above, a redundant description thereof will be omitted.

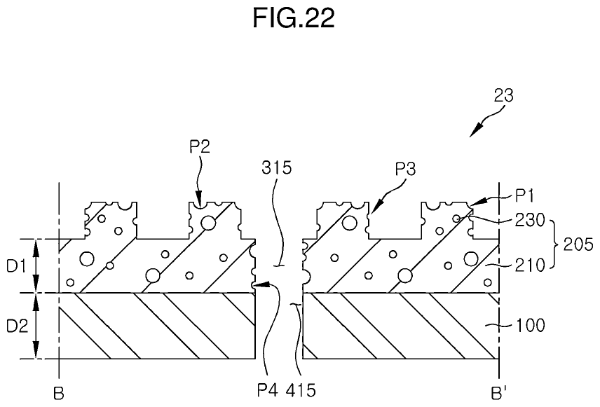

FIG. 22 is a cross-sectional view of a polishing pad in a polishing device according to still another embodiment of the present disclosure, and shows a position corresponding to that of FIG. 6.

Referring to FIG. 22, a polishing pad 23 according to the present embodiment is different from that of the embodiment of FIG. 21 described above in that the support layer 100 is penetrated by a trench.

As described above, a pattern layer 205 has a first trench 315 and the support layer 100 has a second trench 415, and the first trench 315 and the second trench 415 are connected to each other while overlapping each other. In this embodiment, the second trench 415 may completely penetrate the support layer 100. That is, a depth D2 of the second trench 415 may be substantially equal to the thickness of the support layer 100. Accordingly, other components (not shown) under the polishing pad 23 may be visually recognized through the trenches 315 and 415.

Since the first pore P1 to the third pore P3 of the protrusion pattern 230 and the fourth pore P4 of the base 210 have been described above, a redundant description thereof will be omitted.

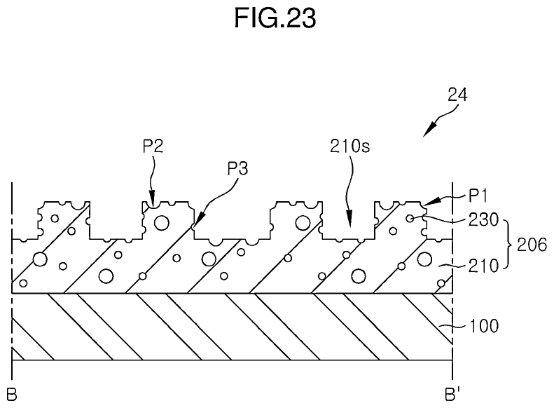

FIG. 23 is a cross-sectional view of a polishing pad in a polishing device according to still another embodiment of the present disclosure, and shows a position corresponding to that of FIG. 6.

Referring to FIG. 23, a polishing pad 24 according to the present embodiment is different from that of the embodiments described above in that the top surface of the base 210 of a pattern layer 206 has pores.

Hereinafter, a method of manufacturing a polishing pad according to one embodiment of the present disclosure will be described.

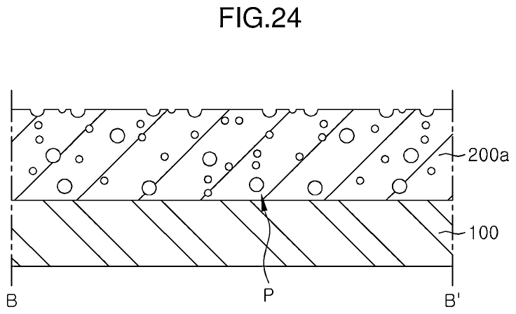

FIGS. 24 to 27 are cross-sectional views sequentially illustrating a method of manufacturing a polishing pad according to one embodiment of the present disclosure, and show a position corresponding to that of FIG. 6.

First, referring to FIG. 24, a porous pre-pattern layer 200a is prepared. Although FIG. 24 illustrates a case in which the pre-pattern layer 200a is disposed on the support layer 100, the present disclosure is not limited thereto, and only the pre-pattern layer 200a may be prepared without the support layer 100.

The pre-pattern layer 200a may be in a pre-cured state to have a predetermined porosity. The average diameter of pores P of the pre-pattern layer 200a may be in a range of about 10 μm to 150 μm. In addition, the diameter distribution of the pores P may be in a range of about 1 μm to 500 μm, or about 5 μm to 400 μm, or about 80 μm to 300 μm.

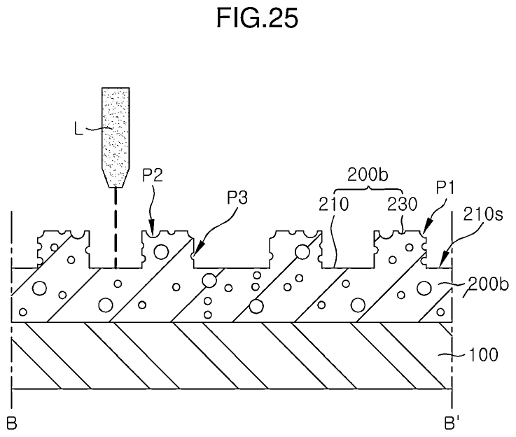

Next, referring further to FIG. 25, the pre-pattern layer 200a is at least partially removed using a laser L. A pattern layer 200b formed by the laser L may include the base 210 and the plurality of protrusion patterns 230 disposed on the base 210.

The side surface of the protrusion pattern 230 formed by the laser L may have the third pore P3. In addition, as described above, the top surface of the protrusion pattern 230 has the first pore P1 and the second pore P2. On the other hand, the top surface 210s of the base 210 formed by the laser L may have substantially no pores, or may have only a relatively smaller number of pores or a relatively smaller size of pores than that of the surface of the protrusion pattern 230. This may be because the pores collapse due to partial melting and the like of the pre-pattern layer 200a in a portion irradiated by the laser L, but the present disclosure is not limited thereto.

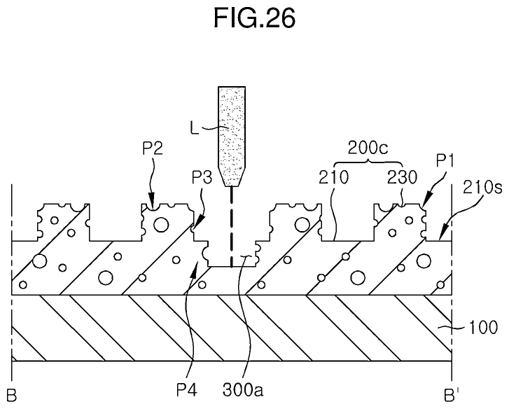

Next, referring further to FIG. 26, a pattern layer 200c is partially removed using the laser L to form a trench 300a in the pattern layer 200c. Specifically, the trench 300a is formed in the base 210 of the pattern layer 200c.

The inner wall of the trench 300a formed by the laser L may have the fourth pore P4. On the other hand, the bottom surface of the trench 300a formed by the laser L may have substantially no pores, or may have only a relatively smaller number of pores or a relatively smaller size of pores than that of the inner wall of the trench 300a.

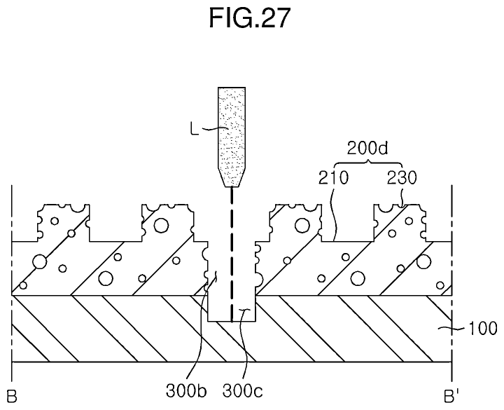

Next, referring further to FIG. 27, a first trench 300b penetrating a pattern layer 200d is formed using the laser L, and the support layer 100 is partially removed to form a second trench 300c in the support layer 100.

Although not shown in the drawing, in some embodiments, a second trench penetrating the support layer 100 may be formed using the laser.

Hereinafter, the present disclosure will be described in more detail with reference to specific preparation examples, a comparative example and experimental examples.

### Preparation Example 1: Preparation of a Polishing Pad Having Protrusion Patterns

Protrusion patterns having the same shape as those of FIG. 18 were formed. In this case, the area occupied by the protrusion patterns was made to be about 10.0% of the total area. The minimum width of the protrusion pattern was about 20 μm. Laser processing was used to form the protrusion patterns. In addition, the pattern layer had porosity, and the average particle size of the pores was 10 μm and the volume ratio thereof was about 25%.

In order to control the perimeter length, various polishing pads were prepared by adjusting the pattern size.

### Preparation Example 2: Preparation of a Polishing Pad Having Protrusion Patterns

A polishing pad having the same shape as that of Preparation Example 1 except that the minimum width of the protrusion pattern was formed to be about 60 μm was manufactured. In order to control the perimeter length, various polishing pads were prepared by adjusting the pattern size.

### Preparation Example 3: Preparation of a Polishing Pad Having Protrusion Patterns

A polishing pad having the same shape as that of Preparation Example 2 except that the average particle size of the pores was 20 μm and a volume ratio was about 40% was manufactured. In order to control the perimeter length, various polishing pads were prepared by adjusting the pattern size.

### Preparation Example 4: Preparation of a Polishing Pad Having Protrusion Patterns

A polishing pad having the same shape as that of Preparation Example 2 except that the pores had an average particle size of 40 μm and a volume ratio of about 40% was manufactured. In order to control the perimeter length, various polishing pads were prepared by adjusting the pattern size.

### Preparation Example 5: Preparation of a Polishing Pad Having Protrusion Patterns

A polishing pad having the same shape as that of Preparation Example 2 except that the pores had an average particle size of 100 μm and a volume ratio of about 30% was manufactured.

### Preparation Example 6: Preparation of a Polishing Pad Having Protrusion Patterns

A polishing pad having the same shape as that of Preparation Example 2 except that the pores had an average particle size of 200 μm and a volume ratio of about 20% was manufactured.

### Experimental Example 1: Removal Rate Depending on Perimeter Length Per Unit Area

The influence of the perimeter length per unit area on the removal rate characteristics was confirmed using the polishing pads according to Preparation Examples 1 to 4. By adjusting the size and the like of the pattern while maintaining the polishing area of about 10%, there were prepared various polishing pads having perimeter lengths of about 1 mm/mm², about 2 mm/mm², about 3 mm/mm², about 4 mm/mm², about 5 mm/mm², about 6 mm/mm², about 7 mm/mm², about 8 mm/mm², about 10 mm/mm², about 15 mm/mm², and about 25 mm/mm². In this case, the pore condition and the minimum width of the pattern maintained the conditions presented in Preparation Examples 1 to 4.

For the polishing experiment, an eight-inch oxide wafer and TSO-12 (Soulbrain) that is a slurry for oxide were used. The apparent contact pressure was set to be 150 g/cm². The apparent contact pressure Pa may be defined as a value obtained by dividing the total load applied to the polishing target substrate by a carrier by the area of the polishing target substrate. The rotation velocity of the polishing pad was fixed at 61 rpm.

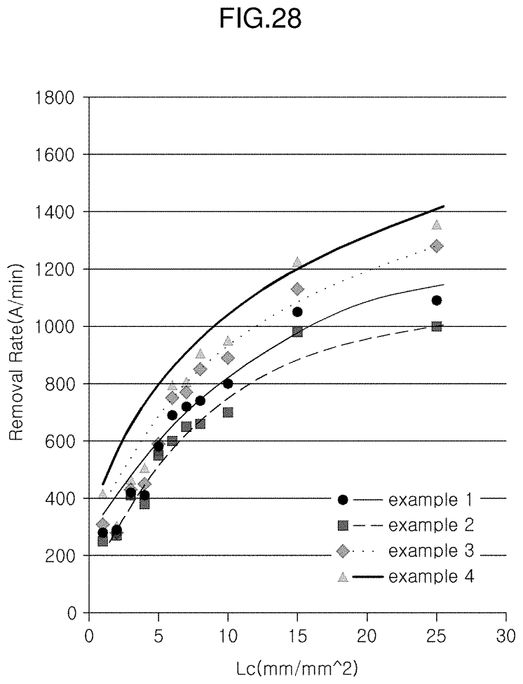

The results thereof are shown in FIG. 28. Referring to FIG. 28, it can be seen that the removal rate increases as the perimeter length per unit area of the protrusion pattern increases. However, it can be seen that the increase in the removal rate is not linear, but gradually decreases and slows down as the perimeter length increases, and converges to a predetermined value. For example, it is expected that the polishing efficiency would converge within 50 mm/mm².

Through this, it was confirmed that the removal rate could be controlled based on the area ratio and the perimeter length.

In particular, comparing Preparation Examples 2 to 4, in which the minimum width of the protrusion pattern is about 60 μm, it can be seen that the removal rate gradually increases even when the perimeter length is the same as the average particle size of the pores increases. Comparing Preparation Example 1 with Preparation Examples 3 and 4, it can be seen that Preparation Examples 3 and 4 exhibit a higher removal rate than that of Preparation Example 1 having a smaller minimum width of the protrusion pattern.

### Experimental Example 2: Removal Rate for Pores

The influence of the average size of the pores on the removal rate characteristics was confirmed using the polishing pads according to Preparation Examples 1 to 5. The perimeter length of the polishing pad was fixed to 15 mm/mm². As a comparative example, an IC1010 pad, which is a commercial polishing pad, manufactured by Dow was used.

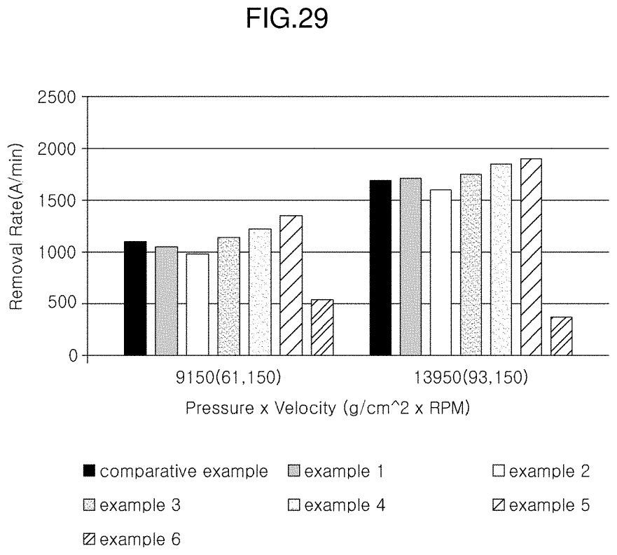

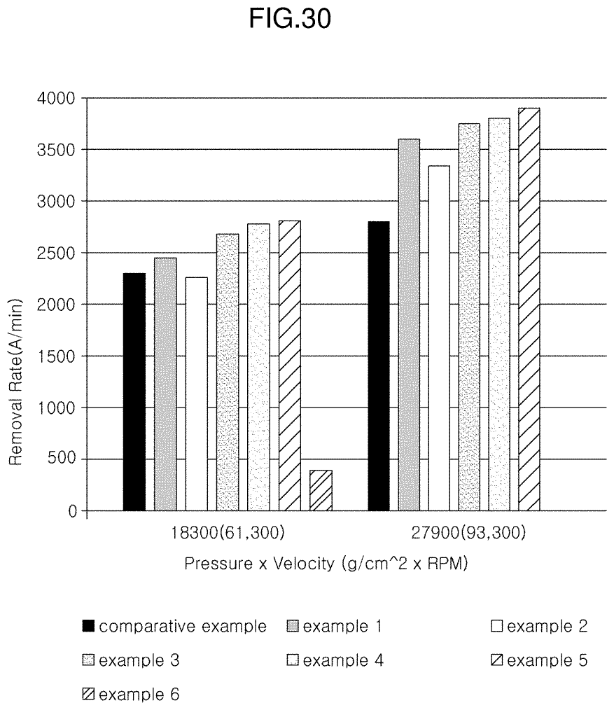

As polishing conditions, the rotation velocity of the pad was set to one of 61 rpm and 93 rpm, and the polishing pressure was set to one of 150 g/cm² and 300 g/cm², and the horizontal axis was expressed as the product of the rotation velocity and pressure. The results thereof are shown in FIGS. 29 and 30.

Referring to FIGS. 29 and 30, it can be seen that the removal rate increases as the size of the pores increases when the protrusion pattern has the same minimum width. In particular, comparing Preparation Example 1 with Preparation Example 3, Preparation Example 3 exhibited a high level of removal rate despite having a larger minimum width. On the other hand, it was confirmed that the polishing efficiency of the polishing pads according to Preparation Examples 3 to 5 of the present disclosure further increased under a higher level of polishing conditions, that is, as the polishing velocity and the polishing pressure increased.

In the case of Preparation Example 6 in which the average particle size of the pores was 200 μm, the pattern shape was collapsed due to the pores, and it was difficult to maintain the polishing area at 10%. In addition, in the case of Preparation Example 6, the measured removal rate was low, and damage to the polishing substrate was observed, so that it could be determined that polishing was not performed.

Although the embodiments have been described above, they are merely examples and not intended to limit the embodiments and it should be appreciated that various modifications and applications not described above may be made by one of ordinary skill in the art without departing from the essential features of the embodiment.

Therefore, it should be understood that the scope of the present invention includes changes, equivalents or substitutes of the technical spirit described above. For example, each component specifically shown in the embodiment of the present invention may be modified and implemented. In addition, it should be understood that differences related to these modifications and applications are within the scope of the present invention as defined in the appended claims.

1. A polishing pad comprising:
a support layer; and
a pattern layer disposed directly on the support layer, the pattern layer comprising a protrusion pattern having a plurality of pores,
wherein the pores contribute to an increase in perimeter length of the protrusion pattern in plan view, and a perimeter length of a polishing surface formed by the protrusion pattern per unit area is in a range of 1.0 mm/mm² to 50.0 mm/mm².

2. The polishing pad of claim 1, wherein a rigidity of the pattern layer is greater than a rigidity of the support layer.

3. The polishing pad of claim 1, wherein in plan view, a ratio of an area occupied by the pores to a total area of a top surface of any one protrusion pattern is 10% to 50%.

4. The polishing pad of claim 1, wherein a perimeter length of any one protrusion pattern is 4 times to 50 times a minimum width of the any protrusion pattern.

5. The polishing pad of claim 1, wherein a perimeter length of the polishing surface formed by the protrusion pattern per unit area is in a range of 0.1 times to 1.0 times a reciprocal of a minimum width of any protrusion pattern.

6. The polishing pad of claim 1, wherein a perimeter length of any protrusion pattern is increased by 1.5 times to 3.5 times compared to a perimeter length when the pores do not exist.

7. The polishing pad of claim 1, wherein a minimum width of the protrusion pattern is 20 μm or more, and
an average diameter of the pores is in a range of 10 μm to 150 μm.

8. The polishing pad of claim 1, wherein in plan view, per unit area, an area occupied by the pores is 0.5% to 20%.

9. The polishing pad of claim 8, wherein in plan view, per unit area, an actual polishing area of the protrusion pattern is 5% to 30%.

10. The polishing pad of claim 1, wherein the pores comprise a third pore which is positioned on a side surface of the protrusion pattern to form a side groove of the protrusion pattern, contributes to an increase in area of the side surface, and affects a flow of slurry during a polishing process, and
an average diameter of the third pores is in a range of 20 μm to 150 μm.

11. The polishing pad of claim 1, wherein a porosity of the support layer is different from a porosity of the pattern layer.

12. A polishing pad comprising:
a support layer; and
a pattern layer disposed on the support layer, the pattern layer comprising a protrusion pattern having a plurality of pores,
wherein the protrusion pattern has pores exposed on a side surface, and
a ratio of a sum of heights occupied by the pores of the side surface to a vertical height of the protrusion pattern is in a range of 10% to 50%.

13. The polishing pad of claim 12, wherein the pattern layer comprises a base and the plurality of protrusion patterns disposed on the base, and a value obtained by subtracting a surface skewness of a surface of the protrusion pattern from a surface skewness of a top surface of the base is greater than 0.

14. The polishing pad of claim 12, wherein the pattern layer comprises a base and the plurality of protrusion patterns disposed on the base, and
an arrangement density of pores on a top surface of the base is smaller than an arrangement density of pores on a surface of the protrusion pattern.

15. The polishing pad of claim 12, wherein an average diameter of the pores is in a range of 20% to 40% of the vertical height of the protrusion pattern.

16. The polishing pad of claim 12, wherein the pattern layer comprises a base and the plurality of protrusion patterns disposed on the base,
the base has an at least partially recessed first trench,
the first trench does not penetrate the base,
a surface skewness of a bottom surface of the first trench is greater than a surface skewness of an inner wall of the first trench.

17. The polishing pad of claim 12, wherein the base has an at least partially recessed first trench,
the support layer has an at least partially recessed second trench which is connected to the first trench,
the base has pores exposed on an inner wall of the first trench,
the support layer has pores exposed on an inner wall of the second trench, and
an average diameter of the pores of the inner wall of the second trench is greater than an average diameter of the pores of the inner wall of the first trench.

18. A polishing device comprising:
a polishing pad according to claim 1; and
a platen configured to support the polishing pad.

19. A manufacturing method of a polishing pad, comprising:
preparing a porous pattern layer; and
partially removing the pattern layer using a laser,
wherein the partially removing of the pattern layer comprises forming a base and a plurality of protrusion patterns disposed on the base, and partially removing the pattern layer to have pores exposed on a side surface of the protruding pattern.

20. The manufacturing method of claim 19, wherein the partially removing of the pattern layer further comprises forming a trench in the base to have pores exposed on an inner wall of the trench.
